(19) United States
(12) Patent Application Publication
(10) Pub. No.: US 2025/0006770 A1
(43) Pub. Date: Jan. 2, 2025

(54) COMPLEMENTARY METAL-OXIDE-SEMICONDUCTOR IMAGE SENSING DEVICES

(71) Applicant: Samsung Electronics Co., Ltd., Suwon-si (KR)

(72) Inventors: Jihun Lim, Suwon-si (KR); Jinyoung Kim, Suwon-si (KR); Myunghae Seo, Suwon-si (KR); Sungki Min, Suwon-si (KR); Chang Kyu Lee, Suwon-si (KR)

(21) Appl. No.: 18/735,325

(22) Filed: Jun. 6, 2024

(30) Foreign Application Priority Data
Jun. 29, 2023 (KR) 10-2023-0084207
Nov. 21, 2023 (KR) 10-2023-0162743

(51) Int. Cl. H01L 27/146

(52) U.S. Cl. CPC H01L 27/14643; H01L 27/14614; H01L 27/14636; H01L 27/14689

(57) ABSTRACT

A dual vertical transfer gate, a transistor including the same, and a CMOS image sensing device including the same. In some embodiments, a gate of the dual vertical transfer transistor may include a pair of poles, which are extended to an n-type region of a photodiode, and a connecting portion, which connects the paired poles to each other. A first insulating pattern may be provided between the poles and on the substrate.

### CROSS-REFERENCE TO RELATED APPLICATIONS

This U.S. non-provisional patent application claims priority under 35 U.S.C. § 119 to Korean Patent Application No. 10-2023-0084207, filed on Jun. 29, 2023, and to Korean Patent Application No. 10-2023-0162743, filed on Nov. 21, 2023, in the Korean Intellectual Property Office, and the entire contents of the above-identified applications are hereby incorporated by reference.

### BACKGROUND

The present disclosure relates to complementary metal-oxide-semiconductor (CMOS) image sensing devices, and in particular, to circuits including transistors with vertical channel gates and to CMOS image sensing devices using the circuits as unit pixel circuits. In addition, the present disclosure relates to methods of fabricating unit pixel circuits with vertical channel gates and CMOS image sensing devices therewith.

An image sensing device or an image sensor is a semiconductor device that is used to convert an optical signal to an electrical signal. The image sensing device may include a wafer and an imaging circuit (e.g., a complementary metal oxide semiconductor (CMOS) device or a charge coupled device (CCD)) that is integrated on the wafer.

Until the 1990s, the CCD image sensor was widely used because its optical characteristics were superior to the CMOS image sensor (CIS). However, after the introduction of a pinned photodiode (PD) and the development of circuit noise reduction technology, the CIS devices with simpler structures and easier fabricating processes are now more widely used.

### SUMMARY

Aspects of the present disclosure provide image sensing devices which include photodiodes (PD) with relatively large charge capacities, even when a device size is reduced due to an increasing demand for a high density device.

Some aspects of the present inventive concepts provide a transistor having a gate with a three-dimensional shape, which may increase transfer efficiency of negative charges.

Some embodiments of the inventive concepts provide an image sensing device preventing a potential hump issue, in which the transfer of negative charges from the inter-pole region to a floating diffusion (FD) region may be hindered by an electric field concentrated to an inter-pole region between a pair of poles, and a backflow issue, in which the negative charges are transferred from the FD region to the inter-pole region.

According to some embodiments of the inventive concepts, a transistor may include a first n-type region below a gate; a gate including a pair of gate poles, which are extended to the n-type region, and a connecting portion, which connects the paired gate poles to each other; a second n-type region adjacent to the gate; and a first insulating pattern placed between the gate poles and on the substrate. In some embodiments, the first insulating pattern may include a composite layer, which is formed of at least one of silicon nitride (SiₓN_{y}), silicon oxide (SiO₂), silicon oxynitride (SiON), silicon carbon oxide (SiOC), silicon carbon nitride (SiCN), or silicon carbon oxynitride (SiOCN). In some embodiments, the first insulating pattern may include a void.

According to some embodiments of the inventive concept, a transistor may include an n-type region of a photodiode placed below a gate; a gate including a pair of poles, which are extended to the n-type region, and a connecting portion, which connects the paired poles to each other; a floating diffusion region adjacent to the gate; and a first insulating pattern placed between the poles and on the substrate.

According to some embodiments of the inventive concepts, a unit circuit may include a first transistor including a first n-type region in a first substrate, a gate including a pair of poles extended to the first n-type region and a connecting portion connecting the paired poles to each other, a second n-type region adjacent to the gate, and a first insulating pattern placed between the poles and on the first substrate; and a second transistor on a second substrate. Here, the second n-type region of the first substrate may be connected to a gate of the second transistor of the second substrate.

According to some embodiments of the inventive concepts, a unit circuit may include a transfer transistor including a PD region in a first substrate, a gate including a pair of poles extended to an n-type region of the PD and a connecting portion connecting the paired poles, an FD region adjacent to the gate, and a first insulating pattern placed between the poles and on the first substrate; and a source follower transistor on a second substrate. Here, the FD region of the first substrate may be connected to a gate of the source follower transistor of the second substrate.

According to some embodiments of the inventive concepts, an image sensing device may include a first substrate including a PD region, a gate including a pair of poles extended to an n-type region of the PD and a connecting portion connecting the paired poles, a first insulating pattern between the poles, and an FD region; a second substrate including a source follower transistor; and a third substrate including a logic circuit. Here, the FD region of the first substrate may be connected to a gate of the source follower transistor of the second substrate.

### BRIEF DESCRIPTION OF THE DRAWINGS

FIG. 1 is a sectional view illustrating a 2-stack CMOS image sensing (CIS) device according to some embodiments of the inventive concepts.

FIG. 2 is a sectional view illustrating a 2-stack CIS device according to some embodiments of the inventive concepts.

FIG. 3 is a sectional view of a 3-stack CIS device according to some embodiments of the inventive concepts.

FIG. 4 is a sectional view illustrating a 3-stack CIS device according to some embodiments of the inventive concepts.

FIG. 5 is a sectional view illustrating a 3-stack CIS device according to some embodiments of the inventive concepts.

FIG. 6 is a sectional view illustrating a 3-stack CIS device according to some embodiments of the inventive concepts.

FIGS. 7A and 7B are circuit diagrams illustrating a structure, in which photodiodes PD are configured to share a unit pixel processing circuit.

FIGS. 8A, 8B, and 8C are circuit diagrams illustrating first and second substrates which are bonded to each other and include photodiodes and a unit pixel processing circuit, respectively, where the unit pixel processing circuit is shared by the photodiodes.

FIGS. 9A and 9B are layouts illustrating a 2-PD share pixel that is configured to include two photodiodes.

FIGS. 10A and 10B are layouts illustrating a 4-PD share pixel that is configured to include four photodiodes.

FIGS. 11A to 11F are side views illustrating a dual vertical transfer gate (dVTG) according to some embodiments of the inventive concepts.

FIGS. 12A and 12B are side views that are provided to define terms and dimensions of a dual vertical transfer gate, when viewed in two different directions.

FIGS. 13A and 13B are side views illustrating a dual vertical transfer gate according to a comparative example.

FIGS. 14A to 141 are diagrams illustrating a process of fabricating a first substrate including a unit pixel circuit, according to some embodiments of the inventive concepts.

FIGS. 15A to 15E are diagrams illustrating a process of fabricating a CIS device including a unit pixel circuit and a logic circuit, according to some embodiments of the inventive concepts.

FIGS. 16A to 16G are diagrams illustrating a process of fabricating a first pixel substrate including a dual vertical transfer gate, according to some embodiments of the inventive concepts.

FIGS. 17A to 17F are diagrams illustrating a process of fabricating a CIS device including a unit pixel circuit and a logic circuit, according to some embodiments of the inventive concepts.

FIG. 18 is a diagram illustrating a process of fabricating a CIS device including a unit pixel circuit and a logic circuit, according to some embodiments of the inventive concepts.

FIGS. 19A to 19D are diagrams illustrating a process of fabricating a CIS device including a unit pixel circuit and a logic circuit, according to some embodiments of the inventive concepts.

FIG. 20 is a diagram illustrating a process of fabricating a CIS device including a unit pixel circuit and a logic circuit, according to some embodiments of the inventive concepts.

FIG. 21 is a flow chart illustrating a process of fabricating a CIS device, according to some embodiments of the inventive concepts.

FIG. 22 is a flow chart illustrating a process of fabricating a first pixel substrate including a dual vertical transfer gate, according to some embodiments of the inventive concepts.

FIG. 23 is a flow chart illustrating a substrate bonding method, according to some embodiments of the inventive concepts.

FIG. 24 is a flow chart illustrating a process flow, depending on a position of an I/O pad and a method of forming the I/O pad.

### DETAILED DESCRIPTION

With increasing demand for high-resolution video, high-density image sensors are increasingly desired. An increase in an integration density of the image sensor may result in a reduction in a size of devices included in the image sensor. That is, as the number of pixels in an image sensor increases, a size of a device in each pixel and an occupying area of a photodiode (PD) in each pixel may also decrease.

To realize a full-well capacity photodiode in a pixel of a reduced size, the photodiode may include an n-type region that is extended from a level, which may be spaced apart from a front surface of a substrate by a specific distance, to a level, which may be adjacent to a rear surface of the substrate. Such a photodiode may be called ‘deep photodiode’.

The deep photodiode may include n-type regions (n-PD), which may be enclosed by an isolation structure (e.g., a p-type region and/or a deep trench isolation (DTI)) so as to be electrically separated from each other. Hereinafter, an n-type region n-PD may be referred to as ‘n-PD region’ for brevity.

A vertical transfer gate (VTG) may be used to effectively collect negative charges from the n-type region having a large vertical depth. The vertical transfer gate may include one or two extending portions (hereinafter, single pole or dual poles), which may be extended to the n-type region of the photodiode formed in the substrate. According to some embodiments, the vertical transfer gate may be provided to have dual poles (e.g., two extending portions), and in this case, it may be possible to improve the charge transfer efficiency of the image sensor, as described below.

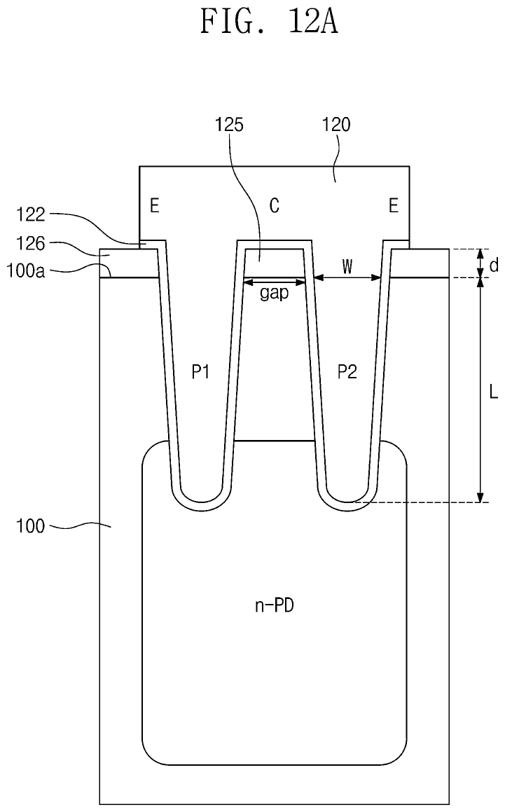

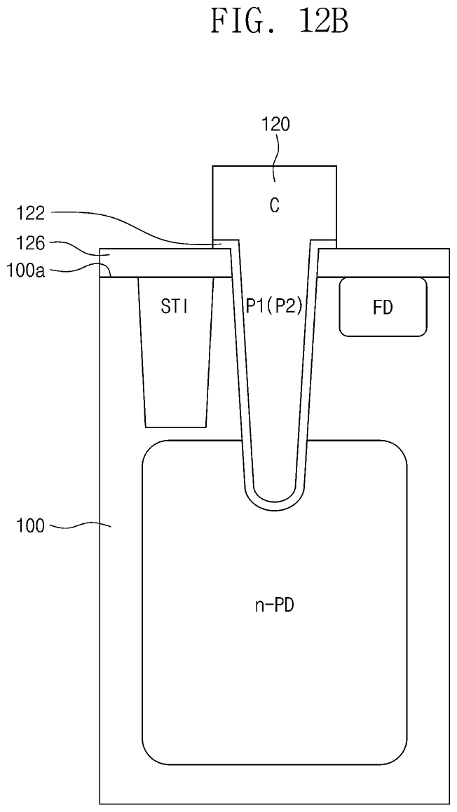

Referring to FIG. 12A, a vertical transfer gate 120 may include a pair of poles P1 and P2, which may be provided in a substrate 100 and may be extended from a substrate surface 100a of the substrate 100 to an n-type region n-PD of a photodiode. A gate insulating layer 122 may be provided between the vertical transfer gate 120 and the substrate 100. The poles P1 and P2 may be extended from the substrate surface 100a by a depth L and may have a width W, when measured at a level of the substrate surface 100a. Furthermore, the vertical transfer gate 120 may include a connecting portion C, which are provided on the substrate 100 to connect the paired poles P1 and P2 to each other, and a gate extending portion E (or first and second gate extending portions E), which may be provided on the substrate 100 and which may be extended outward from the connecting portion C in a horizontal direction. The poles P1 and P2 may be spaced apart from each other by a specific distance or with a predetermined gap.

FIG. 12B is a sectional view of the vertical transfer gate 120, taken in a direction orthogonal to the section of FIG. 12A. In the sectional view of FIG. 12B, the paired poles P1 and P2 are illustrated as one pole, because they are overlapped with each other. A floating diffusion region FD may be formed near the paired poles P1 and P2, and a device isolation region STI may be formed and may separate several regions in the substrate 100 from each other.

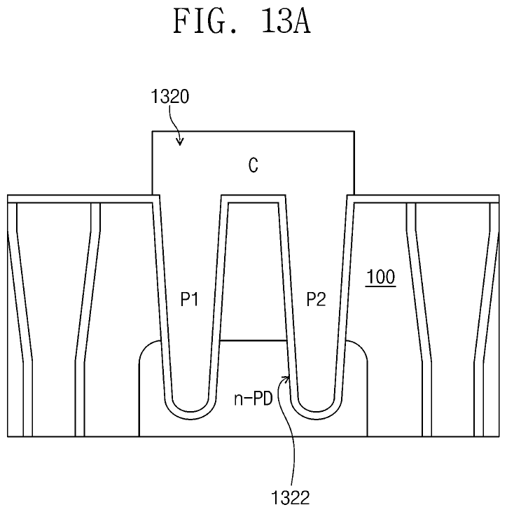

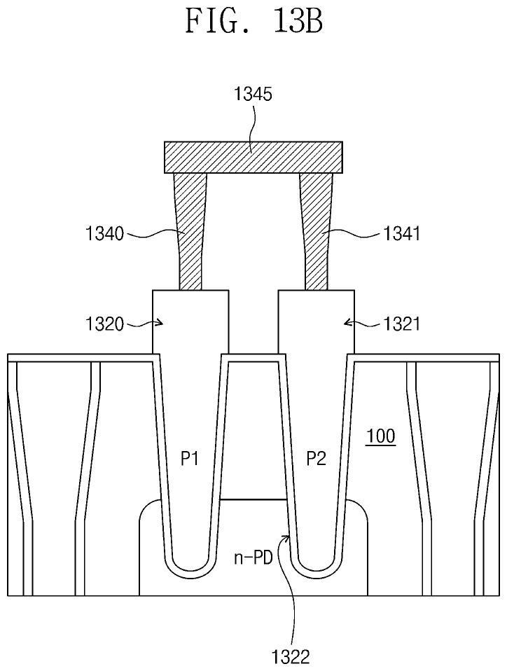

In the case where, as shown in FIG. 13A, a vertical transfer gate 1320 is provided to have the paired poles P1 and P2 extended to the n-PD region of the photodiode, an electric field may be concentrated in a region between the paired poles (hereinafter, an inter-pole region) to produce a potential hump that may hinder the transfer of negative charges from the inter-pole region to the floating diffusion region FD (not shown in FIG. 13A), and a backflow phenomenon may occur where negative charges flow from the floating diffusion region FD to the inter-pole region (i.e., in an undesired direction). Here, FIG. 13A illustrates an image sensor according to a comparative example, and in FIG. 13A, the substrate and the gate insulating layer are identified with the reference numbers 100 and 1322, similar to the embodiment of FIGS. 12A and 12B.

As shown in FIG. 13B, a transfer gate may be provided to include vertical transfer gates 1320 and 1321, each of which has a single pole, and an interconnection line 1345, which is used to connect the vertical transfer gates 1320 and 1321 to each other without the connecting portion C of FIG. 12A. In this case, it may be possible to prevent or suppress the technical issues (i.e., the potential hump and the backflow phenomenon), but there may be other problems, such as a complicate interconnection structure and a misalignment issue in forming contacts 1340 and 1341. Accordingly, as the pixel size reduces, it may become unfavorable in terms of the fabrication process. Here, FIG. 13B illustrate an image sensor according to a comparative example, and each of the reference numbers 1320 and 1321 may refer to a single vertical transfer gate.

In some embodiments, a first insulating pattern 125 may be interposed between the vertical transfer gate 120 and the substrate 100, as shown in FIGS. 12A and 12B, and in this case, an electric field effect between the poles P1 and P2 may be reduced. Furthermore, since the first insulating pattern 125 may be placed in a region that is located between the poles and has a strong field concentration effect, the charge transfer efficiency may be improved. The first insulating pattern 125 will be described in greater detail below.

Below, some examples of embodiments of the inventive concepts will be described with reference to the accompanying drawings.

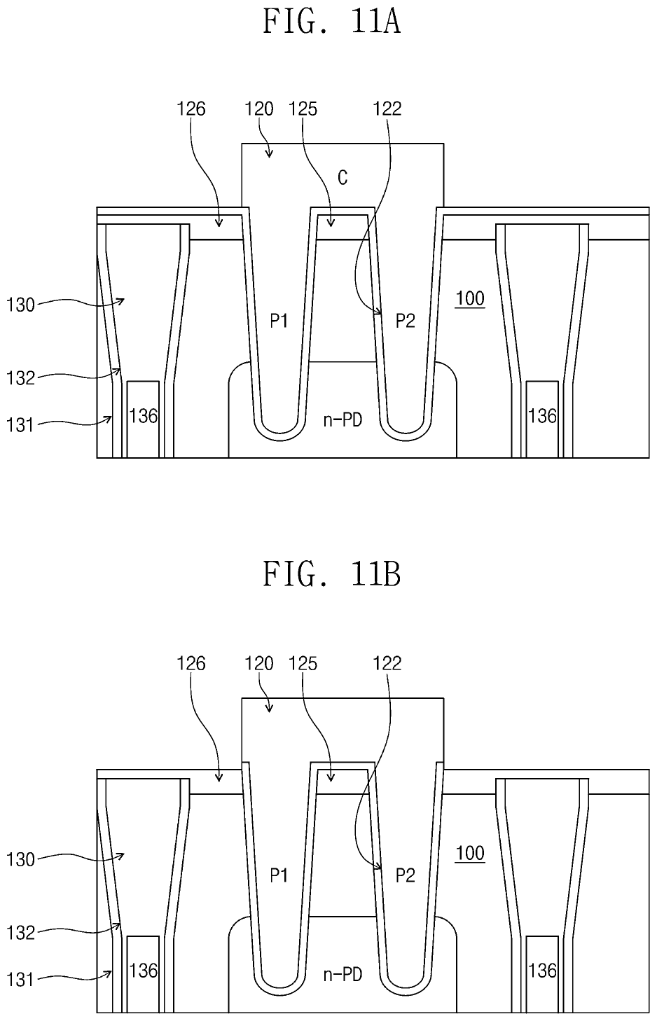

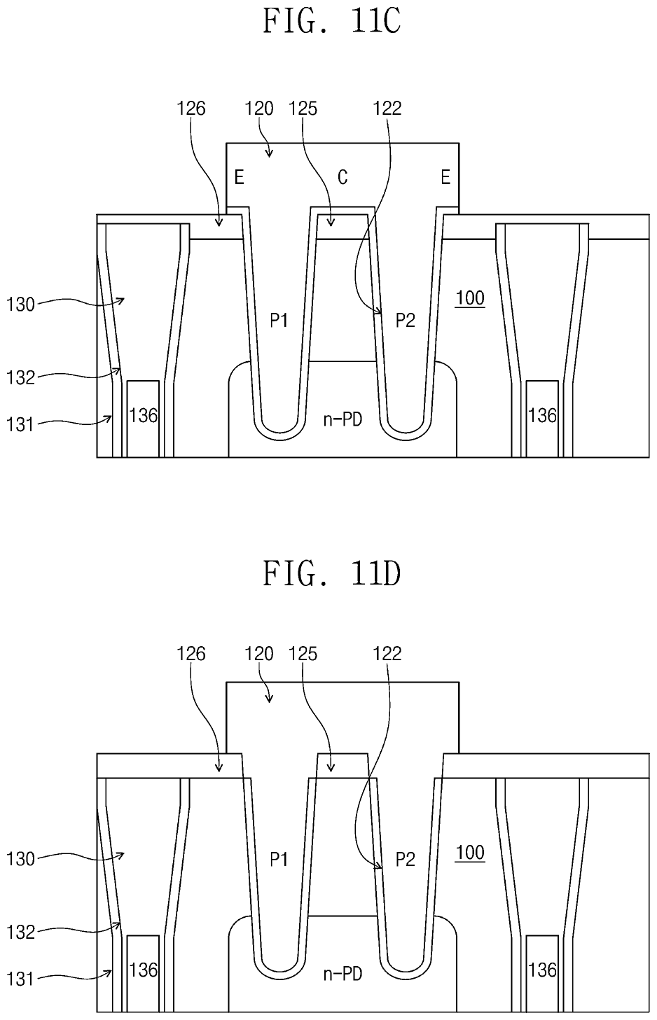

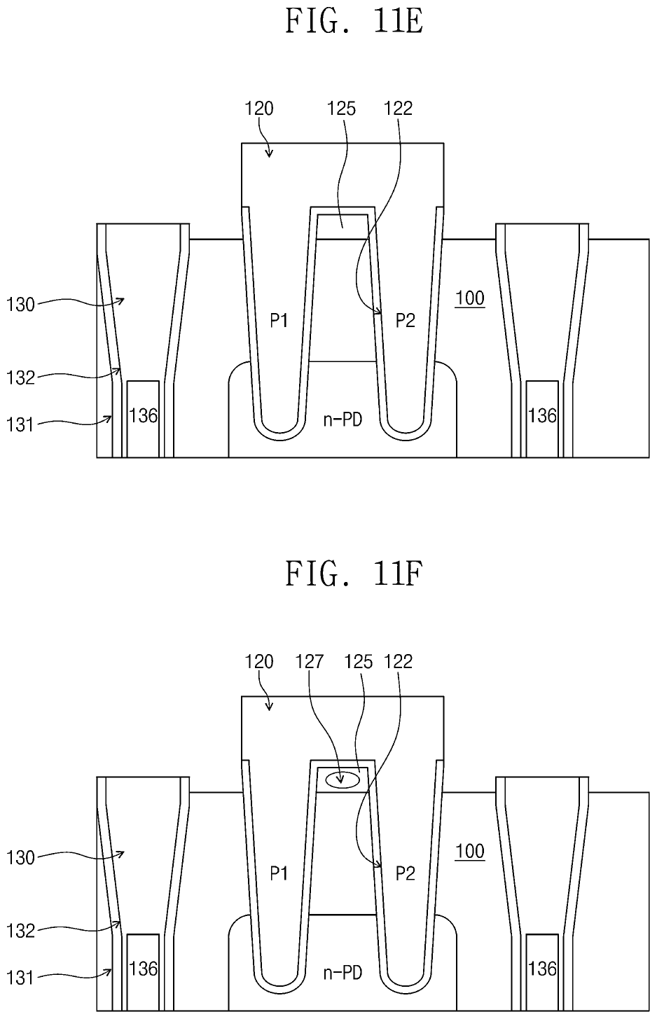

FIG. 11A is a side view of a transfer gate having a dual vertical transfer gate (dVTG) structure. The vertical transfer gate 120 may include a pair of poles P1 and P2, which may be provided in the substrate 100 and which may extend to the n-type region n-PD, and a connecting portion C, which may be provided to connect the paired poles P1 and P2. In addition, although not shown in FIG. 11A, the floating diffusion region FD (e.g., of an n-type) may be provided in the substrate 100 adjacent to the transfer gate 120, as shown in FIG. 12B, when viewed in a direction orthogonal to the section of FIG. 11A.

The substrate 100 may be a base structure, on which a photodiode, a transistor, and a device with an electrode node are formed. The substrate 100 may be a semiconductor wafer and may be divided into IC chips by a sawing process. The substrate 100 may be formed of or include a pure or compound semiconductor material (e.g., silicon or GaN), and in some embodiments, it may be provided as an n- or p-type substrate that is doped with n- or p-type impurities. FIGS. 11A to 11E illustrate an example of an n-type MOS FET device, which may be fabricated by providing a p-type substrate and forming a n-type gate and an n-type source/drain region on and in the p-type substrate. The n-type region n-PD of the photodiode may serve as a source region, and the floating diffusion region FD may serve as a drain region.

A portion of a p-type region of the substrate 100, along with the n-type region n-PD, may constitute a PN junction serving as a photodiode. In an embodiment, a p-doping process may be additionally performed on the p-type region to alter a doping concentration of the p-type region, and the p-type region may be provided to enclose the n-PD region and may be used to separate the pixels from each other, along with an isolation structure 130.

Referring further to FIG. 11A, a first insulating layer 126 may be formed on the substrate 100 and at least in an inter-pole region between a first pole P1 and a second pole P2. At least a portion of the first insulating layer 126 may be interposed between the substrate 100 and the vertical transfer gate 120 and may vertically separate the connecting portion C of the vertical transfer gate 120 from the substrate 100. For example, the first insulating layer 126 may include the first insulating pattern 125, which may be between the connecting portion C and the substrate 100. In this case, it may be possible to reduce a strength of an electric field, which is produced by a portion (e.g., the connecting portion C) of the gate placed on the substrate 100, and thereby to prevent or suppress an undesired phenomenon which may occur when the electric field is concentrated to a region between the paired poles P1 and P2.

In some embodiments, a natural oxide layer may be formed between the first insulating layer 126 and the substrate 100, between the poles P1 and P2, and between the first insulating pattern 125 and the substrate 100. In the case where the first insulating layer 126 includes silicon nitride (e.g., SiₓN_{y} where x and y are real numbers greater than 0), the first insulating layer 126 may further include a thin oxide layer.

As shown in FIG. 11A, the first insulating layer 126 may be provided below the vertical transfer gate 120 and on the substrate 100 and may cover a portion or the entirety of the substrate 100. In some embodiments, the first insulating layer 126 may be used as an etch stop layer.

The gate insulating layer 122 may be interposed between the vertical transfer gate 120 and the substrate 100. In addition, the pixels may be separated from each other by the isolation structure 130, and a photodiode may be formed between the isolation structure 130. The isolation structure 130 may be used to electrically separate adjacent ones of the pixels from each other and may include a single or composite layer that may be formed of at least one insulating material selected from the group consisting of SiO₂, SiₓN_{y}, SiON, and SiOC. In some embodiments, the isolation structure 130 may include a first insulating layer 132 and a second insulating layer 131. The first insulating layer 132 may be an oxide insulating layer (e.g., SiO₂), and the second insulating layer 131 may be a nitride insulating layer (e.g., SiₓN_{y}) that is provided in the form of a liner. Furthermore, the isolation structure 130 may further include a conductive layer 136, which may be provided therein and may be used for applying a bias. The conductive layer 136 may be formed of or include at least one of, for example doped polysilicon or tungsten (W).

FIG. 11B illustrates a structure, in which the gate insulating layer 122 is partially exposed and removed by a patterning process, according to some embodiments of the inventive concepts.

FIG. 11C illustrates the gate extending portion E, which may be horizontally extended on the substrate 100, according to some embodiments of the inventive concepts. Even when the gate extending portion E is present as shown in FIG. 11C, it may be possible to weaken an electric field produced by the gate extending portion E, and this structure may have several advantages of increasing a degree of freedom in designing the gate and a process margin during fabrication processes.

FIG. 11D illustrates the gate insulating layer 122, which may be locally formed in the substrate 100 to cover side and bottom surfaces of the poles P1 and P2, according to an embodiment of the inventive concept. The gate insulating layer 122 may be cut between the poles P1 and P2. The gate insulating layer 122 of this structure may be formed by oxidizing an exposed surface of the substrate 100, and in this case, the gate insulating layer 122 may be formed of silicon oxide. In some embodiments, the process may be modified to improve quality of the gate insulating layer 122 and alter an energy band gap of the gate insulating layer 122. For example, the gate insulating layer 122 may be doped with an element, such as nitrogen, or may be formed to further include another layer.

FIG. 11E illustrates a modified embodiment of FIG. 11B. In greater detail, referring to FIG. 11E, the first insulating pattern 125 may be present between the paired poles P1 and P2, but the first insulating layer 126 on the substrate 100 may be removed. The present embodiment may differ from the embodiment of FIG. 11B in that the first insulating layer 126 may be absent in some embodiments. This structure may be formed by performing a dry etching process on the entire substrate to remove an exposed portion of the first insulating layer 126 and leave the first insulating pattern 125 covered by the gate connecting portion.

FIG. 11F illustrates a structure including a void 127 which may be, partially or fully, formed on the substrate 100 and between the gate poles P1 and P2, according to some embodiments of the inventive concepts. In the case where the void 127 is formed, an effective dielectric constant of the first insulating pattern 125 may be further lowered, and this may make it possible to weaken (e.g., effectively weaken) an electric field between the gate poles P1 and P2. The void 127 may be an empty or solid-free region, which may be defined by at least one of the first insulating pattern 125, the substrate 100 and the gate insulating layer 122.

FIG. 12A is a side view illustrating a dual vertical transfer gate according to some embodiments of the inventive concepts, taken to show the paired poles P1 and P2. FIG. 12B is a side view taken in a direction orthogonal to the section of FIG. 12A.

Hereinafter, the structural and geometrical features of the gate will be described with reference to FIGS. 12A and 12B. The vertical transfer gate 120 may include the paired poles P1 and P2 which may be extended toward a lower portion of the substrate 100. Each of the paired poles P1 and P2 may be provided to have a width W, at a level of the substrate surface 100a, and a depth L, and may be spaced apart from each other by a specific distance, at the level of the substrate surface 100a, or a predetermined gap.

In addition, the paired poles P1 and P2 may have substantially the same size and shape, but in some embodiments, they may have different sizes from each other, depending on the shape and position of the gate. Nevertheless, for convenience in illustration, the drawings are provided to illustrate an example of an embodiment, in which poles have substantially the same features. Each of the poles P1 and P2 may be provided to have a decreasing width as a distance from the substrate surface 100a increases in a downward vertical direction. Furthermore, each of the poles P1 and P2 may have a bottom end, which may be placed in the substrate 100 and may be in contact with the photodiode. Here, the bottom end of each pole may have a curved surface or a rounded shape, and this shape of the bottom end may make it possible to prevent a potential barrier from being formed.

The vertical transfer gate 120 may include the connecting portion C, which may connect the paired poles P1 and P2 to each other, and in some embodiments, it may further include the gate extending portion E, which may be extended in a horizontal direction. The connecting portion C may be used to connect the paired poles to each other and provide a landing place for a contact plug of an interconnection structure thereon.

Referring to FIG. 12B, each of the poles P1 and P2 may be formed (e.g., relatively deeply formed) to extend into the n-type region n-PD of the photodiode and may be placed near (e.g., relatively proximate to) the floating diffusion region FD. In addition, each of the poles P1 and P2 may be adjacent to the device isolation region STI, which may be formed near the substrate surface 100a. If the vertical transfer gate 120 is an NMOS-FET with an n-type doped region, a channel region may be formed around the poles P1 and P2, when the transistor is turned on by a voltage higher than an operation voltage. In this case, negative charges produced in the n-type region n-PD may be transferred to the floating diffusion region FD through the channel region.

Referring to FIG. 12A, the first insulating pattern 125 may be formed to have a substantially constant thickness d on the substrate 100. The thickness d of the first insulating pattern 125 may range from 5 nm to 50 nm, in particular, from 10 nm to 50 nm.

The first insulating pattern 125 may be formed of or include silicon nitride (SiₓN_{y}). Alternatively, the first insulating pattern 125 may be a single or composite layer, which may be formed of at least one of SiON, SiONC, SiO₂, or SiOC. In some embodiments, the first insulating pattern 125 may be provided to have a void, and in this case, it may be possible to suppress an electric field concentration effect.

In some embodiments, when the electric field is concentrated (e.g., relatively strongly concentrated) on a region between the poles P1 and P2 (i.e., the size of the device is reduced), the first insulating pattern 125 may reduce more effectively the strength of the electric field. In some embodiments, a width W of the pole P1 or P2 may range from 50 nm to 200 nm, and a depth L of the poles P1 and P2 may range from 200 nm to 500 nm. An aspect ratio (i.e., L/W) of the poles P1 and P2 may range from 1 to 10, preferably from 1.5 to 10, and more preferably, from 3 to 10. In addition, a distance between the poles P1 and P2 may range from 10 nm to 80 nm, at a level of the substrate surface 100a. As the distance between the poles P1 and P2 decreases, the strength of the electric field may increase, and in the case where the first insulating pattern 125 is formed, the strength of the electric field may be reduced more effectively by the first insulating pattern 125. The distance between the poles P1 and P2 may be substantially equal to or smaller than the width W of the pole. For example, the distance between the poles P1 and P2 may be smaller than the width W of the pole, and in some embodiments, it may be ½ to ⅕ of the width W.

As described above, the smaller the device, the more effectively it may reduce the concentration of the electric field (in particular, for a device having a pixel size smaller than 1.5 m, preferably than 1.2 m, and more preferably than 1.0 m). Here, the pixel size may be the larger of longitudinal and traversal lengths of a unit pixel, in a planar view.

In some embodiments, the image sensing device according to some embodiments of the inventive concepts may be provided to include a vertical transfer gate, which may include the first insulating pattern 125 that is placed on the substrate 100 and at least between the first and second poles P1 and P2 of the vertical transfer gate 120. As the image sensing device becomes more high-performance and miniaturized, a substrate bonding process of forming and boning an additional substrate may be used to fabricate a stack image sensing device with an improved optical efficiency and a high pixel density.

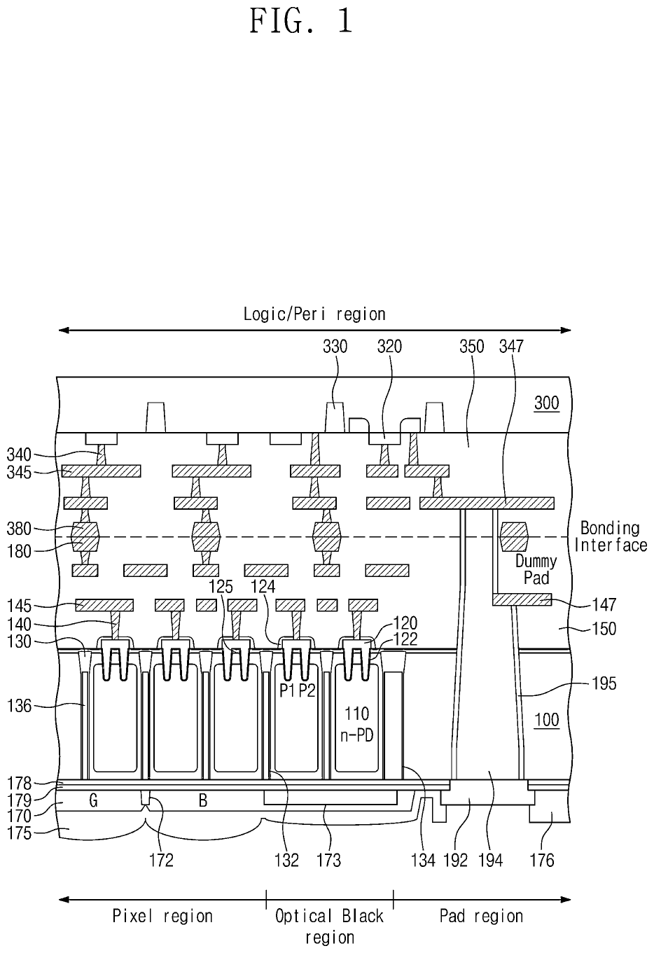

FIG. 1 is a sectional view illustrating a 2-stack CMOS image sensing (CIS) device according to some embodiments of the inventive concepts. Referring to FIG. 1, a pixel substrate 100 and a logic/peripheral substrate 300 may be separately provided. Here, the pixel substrate 100 may include an analog circuit configured to drive the pixel, and the logic/peripheral substrate 300 may include a peripheral circuit, which may be used to supply an electric power and produce various control signals, and a logic circuit (e.g., an ISP block), which may be used to process image signals. Thereafter, a stack image sensing device may be formed by bonding the pixel substrate 100 to the logic/peripheral substrate 300 to face their front surfaces to each other.

Referring to FIG. 1, the isolation structure 130 may be formed in the pixel substrate 100 and may delimit pixels in the pixel substrate 100. The isolation structure 130 may be a deep trench isolation (DTI) that is extended from the front surface of the pixel substrate 100 to the rear surface. In some embodiments, a method of applying a bias may be used to reduce loss of the negative charges, which are optically generated, and increase the optical efficiency, and for this, the conductive layer 136 may be further provided in the isolation structure 130.

A photodiode may be provided in the pixel substrate 100 and between the isolation structures 130, and an n-type region n-PD or 110 of the photodiode may be provided in the pixel substrate 100 and below a device that is placed on the pixel substrate 100. The isolation structure 130 may have the same size or may have at least two different thicknesses, depending on the design and position of the pixel (e.g., see the isolation structure 134).

The pixel substrate 100 may have a front surface and a rear surface. A device (e.g., a transistor) and a node may be formed on the front surface of the pixel substrate 100. A device isolation region may be formed in the front surface of the pixel substrate 100 and may define an active region of the pixel substrate 100, and the vertical transfer gate 120 may be formed on the active region of the pixel substrate 100. The vertical transfer gate 120 may include a pair of poles P1 and P2, which may be extended to the n-PD region toward a bottom of the pixel substrate 100, and a connecting portion C, which may be provided on the pixel substrate 100 and may connect the paired poles to each other. The gate insulating layer 122 may be interposed between the paired poles P1 and P2 and the pixel substrate 100.

The first insulating pattern 125 of a thickness d may be provided on the front surface of the pixel substrate 100. The first insulating pattern 125 may be placed on the pixel substrate 100 and at least between the gate poles P1 and P2. In some embodiments, a void may be formed between the gate poles P1 and P2. In the case where the void is formed, the first insulating pattern 125 may be partially left between the gate poles or may be fully removed.

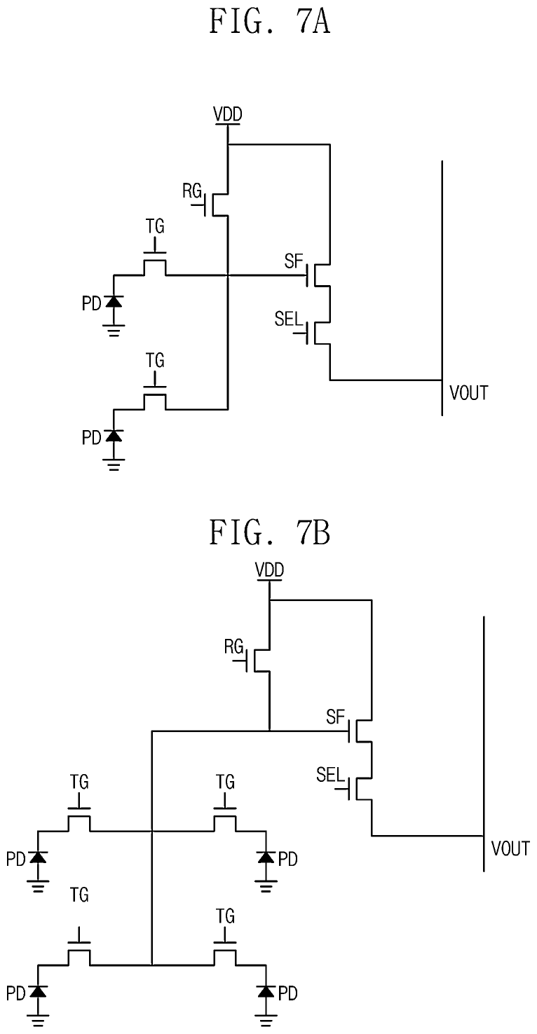

An analog device, which may be used to drive the pixel, may be provided on the front surface of the substrate 100, in addition to the vertical transfer gate 120. As shown in FIGS. 7A and 7B, the image sensing device may include a reset transistor RG, a source follower transistor SF, a selection transistor SEL, and a ground node.

A plurality of interconnection lines 145 and a plurality of contacts 140 may be formed in an interlayer insulating layer 150, which may be provided on the pixel substrate 100. For example, in the embodiment of FIG. 1, the contact 140 may be connected to the connecting portion C of the vertical transfer gate 120 and may be electrically connected to a bonding pad 180 through the interconnection line 145. The bonding pad 180 may include a copper pad and may be bonded and electrically connected to the bonding pad of the substrate paired thereto. The bonding pad 180 may be electrically connected to the bonding pad of the substrate paired thereto, and in some embodiments, a dummy pad may be additionally provided for the substrate bonding.

Meanwhile, in a backside illuminated (BSI) image sensing device, various optical elements may be formed on the rear surface of the substrate 100, to which light may be incident. Referring to FIG. 1, a micro lens 175, RGB color filters 170, a grid 172 may be formed in a pixel region of the rear surface of the substrate 100. The micro lens 175 may be provided to adjust a focal length in each pixel, and in some embodiments, an offset distance from the n-type region 110 of the photodiode may vary as a distance from the center increases.

The pixel substrate 100 may be thinned by, for example, a chemical-mechanical polishing (CMP) to increase light-receiving efficiency of light that is incident through the rear surface of the pixel substrate 100. A second insulating layer 178 may be formed to suppress a negative charge consumption issue. The second insulating layer 178 may be formed of or include at least one of hafnium oxide (HfO₂), aluminum oxide (Al₂O₃), or tantalum oxide (TaOₓ). In addition, an anti-reflection layer 179 may be provided on the second insulating layer 178 and may increase the optical efficiency of the image sensing device. In chemical formula notations herein indicating the composition of inorganic material, x and y may represent the stoichiometric ratios and may be real numbers greater than 0 (e.g., natural numbers). For example, silicon nitride may be represented as SiₓN_{y}, where each of x and y is a real number greater than 0.

A light blocking member 173 may be formed in an optical black region enclosing a pixel array and may be used to observe a reference signal.

Referring further to FIG. 1, various devices may be formed on the front surface of the logic/peripheral substrate 300. For example, a device isolation region 330 may be formed in the logic/peripheral substrate 300 and may define an active region, and a transistor may be formed by forming a gate 320 on the active region. In addition, the interconnection lines 345 and the contacts 340 may be formed on the logic/peripheral substrate 300 and may be electrically connected to the transistors. The interconnection line 345 and the contact 340 may be electrically disconnected from others by an interlayer insulating layer 350. In the present application, the contact 340 may be a conductive element that may be used for a vertical interconnection. The contact 340 may include a via, which may be used to connect the substrate to the interconnection line and connect the interconnection lines to each other.

As described above, the pixel substrate 100 and the logic/peripheral substrate 300 may be bonded to each other by a bonding process. The bonding process may include, for example, a wafer bonding process of bonding wafers to each other, and an electric connection path may be formed, as a result of the bonding between bonding pads. As shown in FIG. 1, the bonding pad 180 of the pixel substrate 100 may be bonded to a bonding pad 380 of the logic/peripheral substrate 300, and a dummy pad may be additionally provided to bond the substrates to each other. The bonding pads 180 and 380 may be formed of or include copper (Cu) and may form a Cu—Cu bonding structure.

According to some embodiments of the inventive concepts, the image sensing device may include an I/O pad, which may be used to transmit and receive signals to and from outside the image sensing device and to receive control signals and an electric power. In some embodiments, since, for the 2-stack backside illuminated structure, the pixel substrate 100 may be provided to have a thin rear portion, the I/O pad may be formed on the rear surface of the pixel substrate 100. Referring to FIG. 1, a penetration electrode 194 (e.g., a through-silicon-via (TSV)) may be provided and may penetrate the pixel substrate 100 through the rear surface of the pixel substrate 100. Here, the penetration electrode 194 may be connected to the interconnection line 145, which may be provided in the pixel substrate 100, and a landing pad 347, which may be provided in the logic/peripheral substrate 300. An insulating layer 195 may be provided between the penetration electrode 194 and the substrate 100 and may electrically separate the substrate 100 from the penetration electrode 194. An I/O pad 192 may be provided on the penetration electrode 194, and an insulating layer and/or a passivation layer may be provided on the rear surface of the substrate and may protect the substrate. In some embodiment, the insulating layer and/or the passivation layer may be formed of or include the same material as the micro lens.

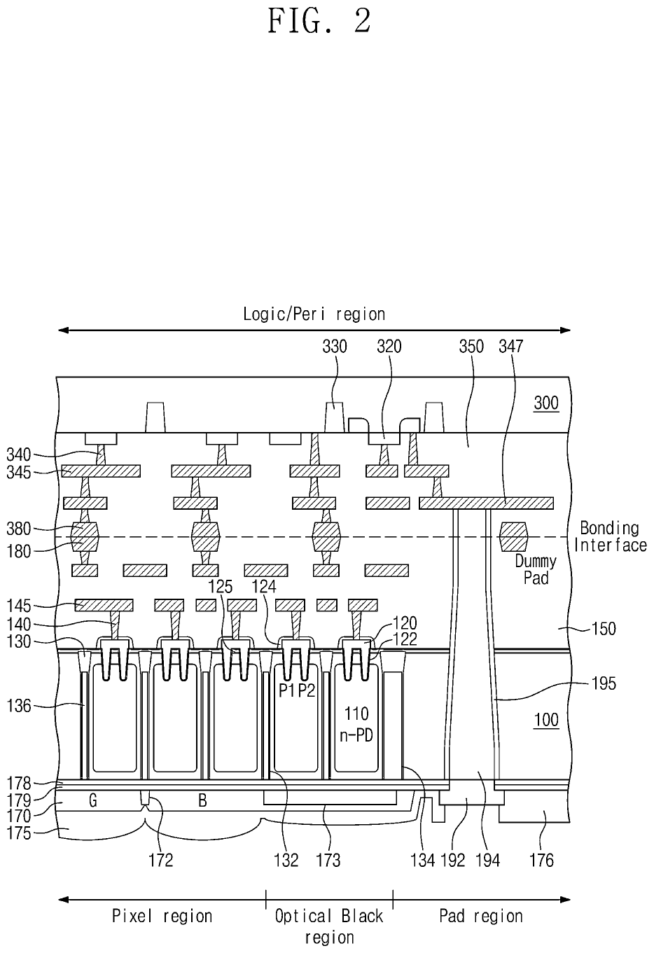

FIG. 2 is a sectional view illustrating a 2-stack CIS device according to some embodiments of the inventive concepts. The embodiment of FIG. 2 may be similar to the embodiment of FIG. 1 but may differ from the embodiment of FIG. 1 in that the penetration electrode 194 that penetrates the pixel substrate 100 may be directly connected to the landing pad 347 in the logic/peripheral substrate 300. The penetration electrode 194 may not be connected to the interconnection line in the pixel substrate 100.

FIG. 2 illustrates a stacking structure, in which the pixel substrate 100 and the logic/peripheral substrate 300 are bonded to each other, as shown in FIG. 1. A substrate bonding process may be performed on a front surface of the pixel substrate 100, and a substrate removing process may be performed on a rear surface of the pixel substrate 100 to increase an amount of light to be incident into the photodiode. As a result, the pixel substrate 100 may have a thickness that is smaller than a thickness of the logic/peripheral substrate 300. Thus, a method of forming an I/O pad structure including the penetration electrode 194 to penetrate through the rear surface of the pixel substrate 100 may be used to facilitate the fabrication process.

In some embodiments, a 2-stack pixel substrate may be fabricated by separately forming a pixel circuit on two substrates and bonding the two substrates to each other. Then, a 3-stack image sensing device may be fabricated by bonding the 2-stack pixel substrate to the logic/peripheral substrate.

FIGS. 7A to 7B are a circuit diagram of a unit pixel processing circuit that is shared by photodiodes PD. FIG. 7A illustrates a structure, in which two photodiodes PD share a unit pixel processing circuit, and FIG. 7B illustrates a structure, in which four photodiodes PD share a unit pixel processing circuit.

Referring to FIG. 7A, each photodiode PD may include a p node, which may be connected to the ground, and an n node, which may be connected to a source of a transfer transistor TG. A drain of the transfer transistor TG may be connected to the floating diffusion region FD (not shown in FIG. 7A). The photodiodes PD may be connected to the floating diffusion region FD through respective transfer transistors TG to share the floating diffusion region FD. If the gate of the transfer transistor TG is turned on, negative charges in the corresponding photodiode PD may be transferred to the floating diffusion region FD. The floating diffusion region FD may also be connected to a source of the reset transistor RG and a gate of a source follower transistor SF. If the reset transistor RG is turned on, electric chares may be removed from the floating diffusion region FD, and this operation may be performed to set a reference point of the electric potential. When the reset transistor RG is turned off, the source follower transistor SF may serve as a common drain amplifier, which generates a gate voltage based on an amount of charges in the floating diffusion region FD and transfers a corresponding analog signal to a bit line Vout. Drain regions of the reset transistor RG and the source follower transistor SF may be connected to a Vdd node. In the case where a selection transistor SEL is turned on, one of pixels sharing the bit line may be selected. In the present specification, the transistors may be nMOS transistors, unless the context clearly indicates otherwise.

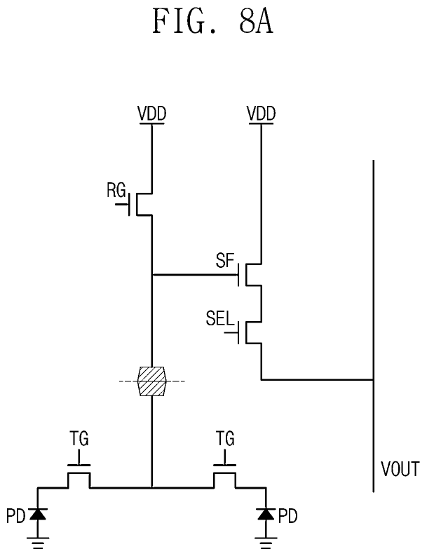

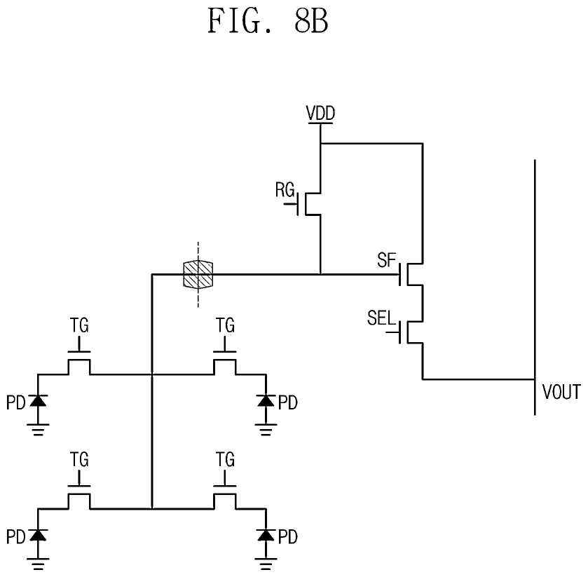

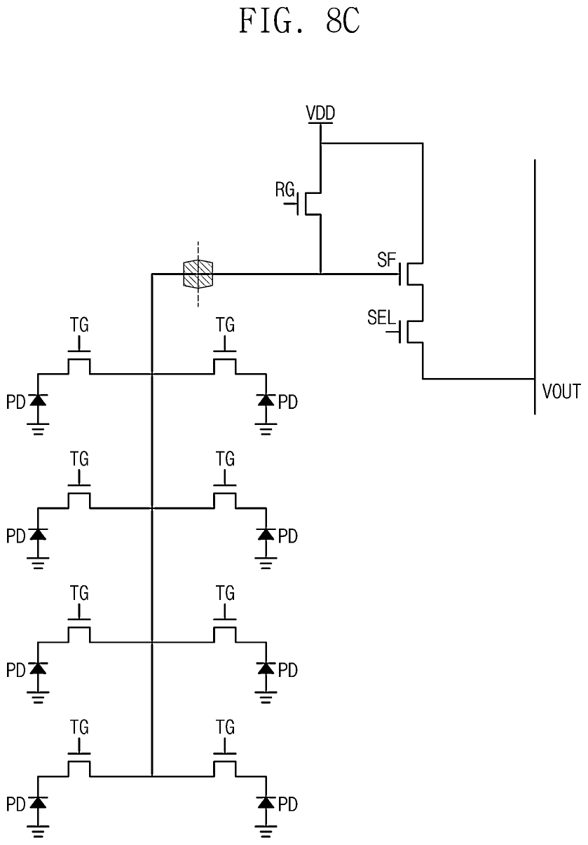

Referring to the embodiments in accordance with FIGS. 7A and 8A, the photodiode PD, the transfer transistor TG, the floating diffusion region FD, and the ground node may be formed in or on a first pixel substrate, and a unit pixel circuit shared may be formed on an additional substrate (i.e., a second pixel substrate).

FIG. 8A is a circuit diagram of a structure, which may be formed by bonding the first pixel substrate, in which the photodiode PD, the transfer transistor TG, the floating diffusion region FD, and the ground node are formed, to the second pixel substrate, in which a unit pixel circuit including the reset transistor RG, the source follower transistor SF, and the selection transistor SEL is formed, in a wafer-bonding process (e.g., a Cu—Cu bonding process). In this case, it may be possible to realize an analog device of a sufficiently large size within a small pixel size and thereby to fabricate a highly precise, high-performance image sensing device.

Furthermore, in the embodiments according to FIG. 8A, it may be possible to simplify the interconnection structure of the image sensing device. For example, the bit line may be omitted from the first pixel substrate with the photodiode PD, the transfer transistor TG, the floating diffusion region FD, and the ground node (GND), and thus, the number of the interconnection lines may be reduced. In some embodiments, the interconnection lines of the first pixel substrate may be provided to form a double-layered structure, but in some embodiments, they may be provided to form a single-layered structure, if the number of the Cu bonding pads is not counted.

FIG. 7B is a circuit diagram illustrating a structure, in which four photodiodes PD are provided and may share one floating diffusion region (not shown) and a unit pixel circuit (including the transistors RG, SF, and SEL). However, the number of the photodiodes PD sharing the unit pixel circuit is not limited to two or four, and as shown in FIG. 8C, eight photodiodes PD may be provided to share the unit pixel circuit. Depending on the circuit structure, the number of the sharing photodiodes PD may be increased to 16 or greater.

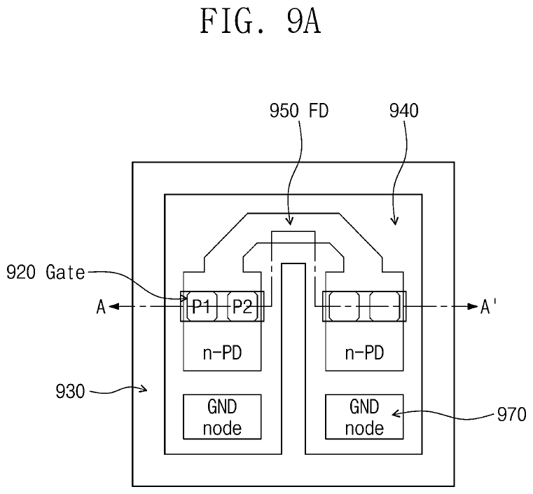

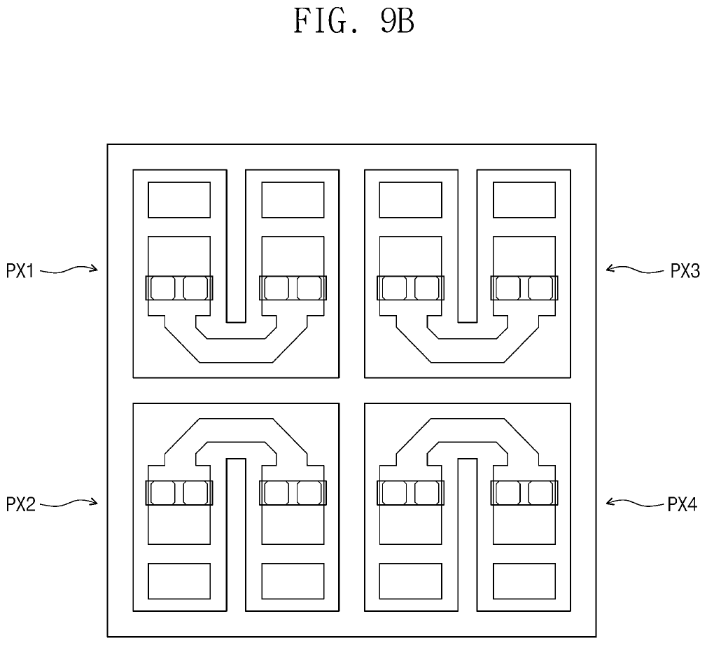

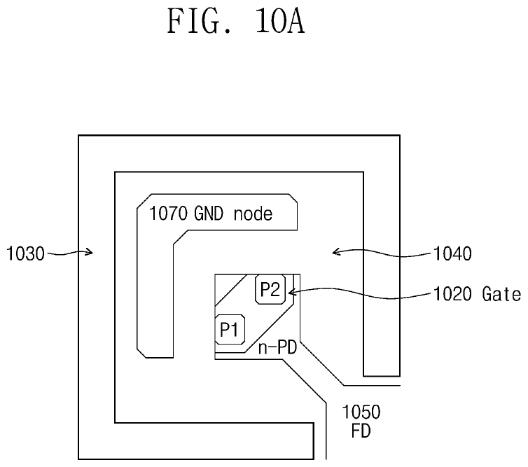

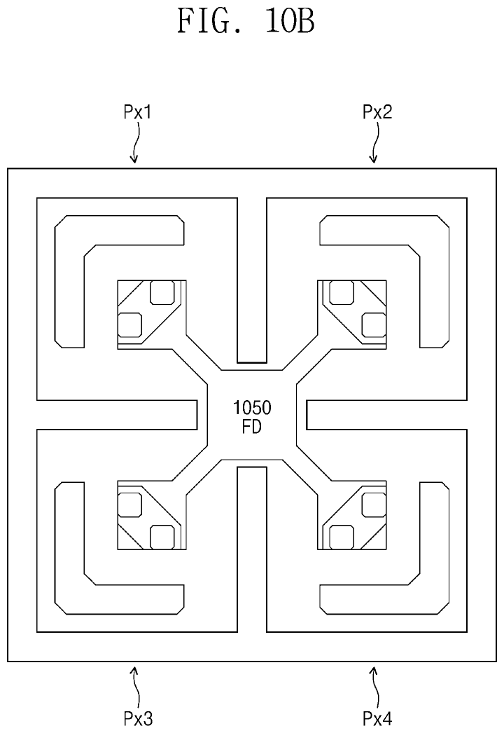

In addition, the four photodiodes PD may be separately operated, as shown in FIGS. 10A and 10B. Alternatively, two photodiodes PD may be operated in a paired manner, as shown in FIGS. 9A and 9B. In the paired operation method, the photodiodes may be used as an individual photodiode in a high-brightness mode, and the two photodiodes may be used as a single photodiode in a low-brightness mode. Referring to FIG. 8B, the embodiment of FIG. 7B may be modified to use a plurality of pixel substrates as described with reference to FIG. 8A.

FIGS. 9A, 9B, 10A, and 10B are plan views, each of which illustrates a first pixel substrate, which includes the photodiode PD, the transfer transistor TG, the floating diffusion region FD, and the ground node, according to some embodiments of the inventive concepts.

Referring to FIGS. 9A and 9B, when the first pixel substrate is viewed from above, a unit pixel may be delimited by an isolation structure 930. The unit pixel may include at least one active region, which may be defined by another isolation structure 940, such as the device isolation region STI.

A transfer gate 920 may be provided between the n-type region n-PD of the photodiode and the floating diffusion region FD or 950 to open or close a conduction path from the n-type region n-PD to the floating diffusion region FD. The transfer gate 920 may include a pair of poles P1 and P2, which may be extended (e.g., deeply extended) toward a bottom of the substrate. The transfer gate 920 may further include a connecting portion C, which is provided on the substrate and may electrically connect the paired poles P1 and P2 to each other. In the embodiments according to FIG. 9A, the gate may have a rectangular shape, when viewed in a plan view, and the paired poles P1 and P2 may be provided in a symmetric manner and with the same feature. However, the shape of the gate may be changed depending on the disposition of the device in the pixel. The paired poles P1 and P2 may be provided in an asymmetric manner or with different features. In some embodiments, the first insulating pattern, and not the gate insulating layer, may be formed on the substrate and between the poles.

The floating diffusion region FD or 950 may be shared by the n-type regions n-PD of two photodiodes, and a contact, which may be connected to the second pixel substrate, may be placed on the floating diffusion region FD.

A ground node 970 may be spaced apart from the n-PD region. The ground node 970 may be used to apply a ground voltage to the p-type region of the photodiode.

Referring further to FIG. 9A, the two photodiodes PD may be operated in pair, and two adjacent pixels may share one of the lenses. The two adjacent pixels may be operated as individual pixels in a high-brightness mode and may be used as a single pixel in a low-brightness mode.

FIG. 9B illustrates a portion of the 2-PD share pixel array of FIG. 9A (including two adjacent pixels). A floating diffusion region (not shown) of a first share pixel PX1 may be arranged to face a floating diffusion region (not shown) of a second share pixel PX2, which may be placed under the same in a vertical direction. In the case where the pixels are arranged to face each other, the floating diffusion region of the first share pixel PX1 may be connected (e.g., relatively easily connected) to the floating diffusion region of the second share pixel PX2.

Meanwhile, two 2-PD share pixels (e.g., the pixels PX1 and PX2 or the pixels PX3 and PX4) may share an analog circuit in one pixel, even when they are connected to the circuit (e.g., including the source follower transistor SF, the reset transistor RG, and the selection transistor SEL) formed on the second pixel substrate. In this case, it may be possible to increase (e.g., efficiently increase) an integration density of the device and increase a size of an analog circuit under the limitation of a small pixel size. As a result, it may be possible to improve characteristics of the device.

The embodiments according to FIG. 9B may include an embodiment in which one 2-PD share pixel of the first pixel substrate is connected to the pixel analog unit circuit of the second pixel substrate, and such an embodiment may correspond to the connection of FIG. 8A. Another embodiment, in which two 2-PD share pixels are arranged, may correspond to the circuit connection of FIG. 8B.

The analog circuit formed on the second pixel substrate may be fabricated by a process different from that for the first pixel substrate. In some embodiments, the transfer gate of the first pixel substrate may be provided in the form of a dual vertical transfer gate having a pair of poles, and the first insulating pattern may be provided on the substrate. By contrast, for the second pixel substrate, the first insulating pattern may not be formed on the substrate, and a plane-type gate or a FinFET-type gate may be formed thereon. Furthermore, the gates may be formed by different processes or in different shapes, depending on the types of the devices on the second pixel substrate.

FIGS. 10A and 10B are plan views illustrating a 4-PD sharing pixel, in which four photodiodes PD are provided to form one pixel. FIG. 10A is an enlarged view of a first sub-pixel Px1 of FIG. 10B.

Referring to FIG. 10A, when the first pixel substrate is viewed from above, a unit pixel may be delimited by an isolation structure 1030. The unit pixel may include at least one active region, which may be defined by another isolation structure 1040, such as the device isolation region STI.

A transfer gate 1020 may be provided between the n-type region n-PD of the photodiode and the floating diffusion region FD or 1050 to open or close a conduction path from the n-type region n-PD to the floating diffusion region 1050. The transfer gate 1020 may include a pair of poles P1 and P2, which may be extended (e.g., deeply extended) to the n-type region n-PD toward a bottom of the substrate.

In addition, the gate may be extended in a diagonal direction and may be formed to have a shape that is suitable for the shape of the n-PD region exposed to the surface of the substrate. For example, the gate may be formed to have a polygonal or rectangular shape. The connecting portion C may be provided on the transfer gate 1020 to electrically connect the paired poles P1 and P2 to each other.

In the embodiments according to FIG. 10A, the gate may have a polygonal shape, when viewed in a plan view, and the paired poles P1 and P2 may be provided in a symmetric manner and with the same feature. However, the shape of the gate may be changed depending on the disposition of the device in the pixel. The paired poles P1 and P2 may be provided in an asymmetric manner or with different features. In an embodiment, the first insulating pattern 125, not the gate insulating layer, may be formed on the substrate and between the paired poles P1 and P2.

As shown in FIG. 10B, the isolation structure 1030 may not be extended to a center portion and may have an opened shape, four sub-pixels Px1, Px2, Px3, and Px4 may share the floating diffusion region FD or 1050, and a contact connected to the second pixel substrate may be placed on the floating diffusion region 1050.

Referring to FIG. 10A, a ground node 1070 may be spaced apart from the n-PD region. The ground voltage may be applied to the p-type region of the photodiode through the ground node 1070.

Referring to FIG. 10B, the four photodiodes PD may be operated together, and the four sub-pixels Px1, Px2, Px3, and Px4 may share one lens. In a high-brightness mode, each of the photodiodes PD may be separately operated as an individual pixel, and in a low-brightness mode, at least two of the photodiodes PD may be configured to function as a single pixel. The configuration of the 4-PD share pixel shown in FIG. 10B may correspond to the circuit diagram of FIG. 8B. In this case, each of the photodiodes PD of FIG. 10B may mean the photodiode of the sub-pixel. Even in this 4-PD share pixel configuration, by connecting the pixel analog circuit of the second pixel substrate to the 4-PD share pixels, it may be possible to construct a circuit, in which eight sub-pixels are shared, as shown in FIG. 8C, or extend the circuit to a structure sharing sixteen or more sub-pixels.

In addition, as in the embodiment of FIGS. 9A and 9B, the second pixel substrate in the embodiment of FIGS. 10A and 10B may be fabricated by a process different from that for the device of the first pixel substrate, and the devices of the second pixel substrate may be formed to have gates with different shapes or sizes from each other.

According to some embodiments of the inventive concepts, a 3-stack CIS device may be provided to include two pixel substrates and one logic/peripheral substrate.

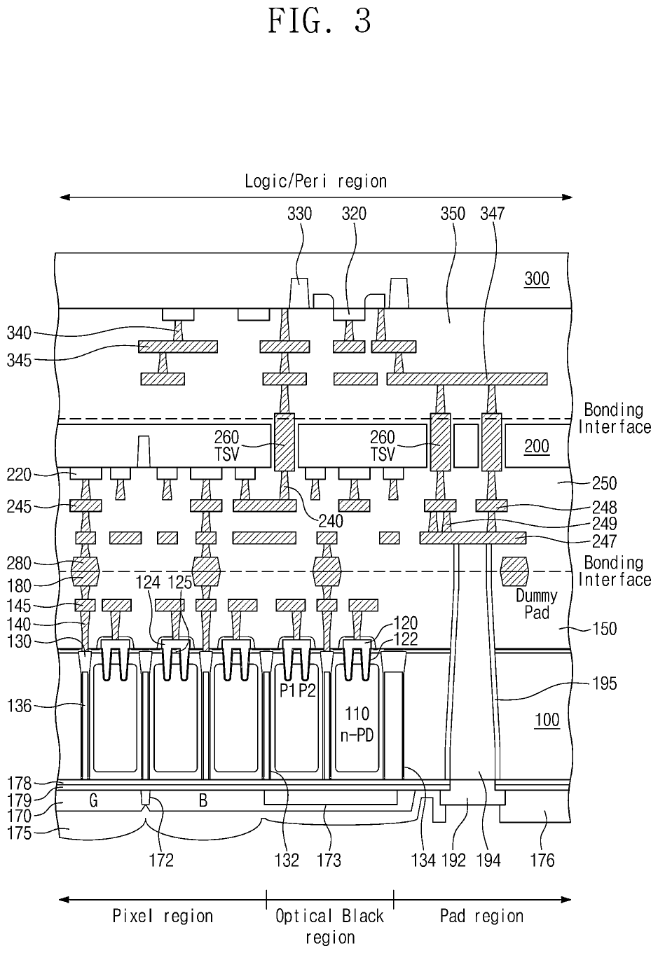

FIG. 3 is a sectional view illustrating a 3-stack CIS device including two pixel substrates and one logic/peripheral substrate. Referring to FIG. 3, a stack image sensing device may be provided to include a first pixel substrate 100, a second pixel substrate 200, and a logic/peripheral substrate 300, which may be bonded to each other. Here, the first pixel substrate 100 may include a light-receiving element, a photodiode, and a transfer gate, and the second pixel substrate 200 may include a pixel analog circuit converting optical signals, which are generated in the photodiode, to analog signals. The logic/peripheral substrate 300 may include a peripheral circuit, which is used for a power supply and generation of various control signals, and a logic circuit (e.g., ISP block), which is used to process image signals.

FIG. 3 illustrates an example, in which the devices are on the first pixel substrate 100 along the line AA′ of FIG. 9A. The isolation structure 130 may be formed in the first pixel substrate 100 and may delimit pixels. The isolation structure 130 may be a deep trench isolation (DTI) that may be extended from the front surface of the first pixel substrate 100 toward the rear surface. Other features (e.g., related to the conductive layer 136 provided in the isolation structure and used for applying a bias, the changing of the thickness of the isolation structure, and the device isolation region) may be substantially the same as those in the embodiment of FIG. 1.

A photodiode may be provided in the first pixel substrate 100 and between the isolation structures 130, and an n-type region n-PD or 110 of the photodiode may be provided in the first pixel substrate 100 and below a device that may be placed on the first pixel substrate 100.

The first pixel substrate 100 may have a front surface and a rear surface. The vertical transfer gate 120 may be formed on the front surface of the first pixel substrate 100. The vertical transfer gate 120 may include a pair of poles P1 and P2, which may be extended to the n-PD region toward a bottom of the first pixel substrate 100, and a connecting portion C, which may be provided on the first pixel substrate 100 and may connect the paired poles P1 and P2 to each other. The gate insulating layer 122 may be interposed between the paired poles P1 and P2 and the first pixel substrate 100.

The first insulating pattern 125 may be on the front surface of the substrate 100. The first insulating pattern 125 may be placed on the first pixel substrate 100 and at least between the gate poles P1 and P2. In some embodiments, a void may be formed between the gate poles P1 and P2. In the case where the void is formed, the first insulating pattern 125 may be partially left between the gate poles or may be fully removed.

A single pixel (e.g., the n-type region n-PD of the photodiode PD, the vertical transfer gate 120, and the ground node (GND, not shown)) may be on the first pixel substrate in a manner of providing a single pixel or a pixel sharing a pair of 2-PDs, as illustrated in FIGS. 9A and 9B, or in a manner of sharing four sub-pixels, as illustrated in FIGS. 10A and 10B.

FIG. 3 illustrates an example of the pixel shown in FIGS. 9A and 9B. When viewed in a section taken along a line AA′ of FIG. 9A, a floating diffusion region (not shown) may be formed in a region of the first pixel substrate 100, which may be located near the front surface of the first pixel substrate 100, between the vertical transfer gates 120, and behind the isolation structure 130. A contact may be formed on the floating diffusion region FD and may be connected to a gate 220 of the source follower transistor through the pads 180 and 280 that are bonded to each other.

Various interconnection lines 145 and various contacts 140 may be provided in the interlayer insulating layer 150 on the first pixel substrate 100. For example, in embodiments according to FIG. 3, the contact 140 may be provided on the connecting portion C of the vertical transfer gate 120 and may be electrically connected to the bonding pad 180 via the interconnection line 145. The bonding pad 180 may include a copper pad and may be bonded and electrically connected to a corresponding one of the bonding pads 280 on the second pixel substrate 200. The bonding pads 180 and 280 may be electrically connected to other conductive structures, but in some embodiments, a dummy pad may be further provided for the substrate bonding.

Meanwhile, in the backside illuminated (BSI) image sensing device shown in FIG. 1, various optical elements may be formed on the rear surface of the substrate 100, to which light may be incident. Referring to FIG. 3, the micro lens 175, the RGB color filters 170, and the grid 172 may be formed in a pixel region of the rear surface of the substrate 100. The offset placement of the micro lens 175, the chemical-mechanical polishing, the formation of a backside insulating layer, and the optical black region may be substantially the same as those in the embodiment of FIG. 1.

The second pixel substrate 200 including a pixel analog circuit may be formed, as shown in FIG. 3. The pixel analog circuit may include the source follower transistor SF, the reset transistor RG, and the selection transistor SEL, as shown in the circuit diagram of FIG. 7A. The pixel analog circuit formed on the second pixel substrate 200 may be used to convert an optical signal, which is generated in the photodiode, to an analog signal. The pixel analog circuit may be formed on an active region, which is delimited by the device isolation region STI.

The first pixel substrate 100 may be bonded to the second pixel substrate 200. In embodiments according to FIG. 3, the first pixel substrate 100 and the second pixel substrate 200 may be bonded to each other in a face-to-face bonding manner. The interlayer insulating layer 150 of the first pixel substrate 100 may be bonded to an interlayer insulating layer 250 of the second pixel substrate 200 to form a bonding interface therebetween.

In addition, devices or circuits of two substrates may be electrically connected to each other, as a result of the bonding of the bonding pads at the bonding interface. The gate 220 of the source follower transistor SF may be connected to the floating diffusion region FD of the first pixel substrate 100. The bonding pad 180 of the first pixel substrate 100 and the bonding pad 280 of the second pixel substrate 200 may be copper-including bonding pads.

The pixel analog circuit of the second pixel substrate 200 may be connected to one of the pixels on the first pixel substrate 100 or to a plurality of pixels on the first pixel substrate 100. In the case where, as shown in FIG. 3, the pixel unit circuit is separately placed on two substrates, it may be possible to effectively place the device within a small pixel region. If a portion of the analog circuit is placed on the second substrate, it may be possible to increase the size of the analog circuit and thereby to improve signal characteristics (e.g., signal noise ratio (SNR)) of the CIS device.

Referring to FIG. 3, the second pixel substrate 200 may be placed between the first pixel substrate 100 and the third logic/peripheral substrate 300, and a via penetration electrode 260 may be provided and may penetrate the second pixel substrate 200 and connect a device of the first pixel substrate 100 to a device of the third logic/peripheral substrate 300. An opening may be formed and may penetrate the second pixel substrate 200, and then, an insulating layer may be formed in the opening or on an exposed surface of the second pixel substrate 200 and may electrically separate the penetration electrode 260 from the second pixel substrate 200. In some embodiments, the penetration electrode 260 may be formed by a substrate etching process including a dry etching process and/or a wet etching process. In addition, a chemical-mechanical polishing (CMP) process may be performed on the second pixel substrate 200 to thin the second pixel substrate 200. In the case where a TSV process is performed after the thinning of the second pixel substrate 200, an aspect ratio of the penetration electrode 260 may be lowered. The penetration electrode 260 may be formed and may penetrate the second pixel substrate 200 through the rear surface of the second pixel substrate 200.

Referring further to FIG. 3, various devices may be formed on the front surface of the logic/peripheral substrate 300. For example, a transistor may be formed by forming the device isolation region STI in the logic/peripheral substrate 300 to define an active region and forming a gate 320 on the active region. In addition, various interconnection lines 345 and contacts 340, which are electrically connected to the transistor, may be formed on the logic/peripheral substrate 300. The interconnection line 345 and the contact 340 may be electrically disconnected from others by the interlayer insulating layer 350.

There may be a bonding interface between the logic/peripheral substrate 300 and the second pixel substrate 200. In some embodiments, the logic/peripheral substrate 300 and the second pixel substrate 200 may be bonded to each other in such a way that the front surface of the logic/peripheral substrate 300 is bonded to the rear surface of the second pixel substrate 200. The second pixel substrate 200 and the logic/peripheral substrate 300 may be bonded to each other by a bonding process. The bonding process may include, for example, a wafer bonding process of bonding wafers to each other, and an electric connection path may be formed between the logic/peripheral substrate 300 and the second pixel substrate 200, as a result of the bonding between bonding pads. In this case, additional processes may be further performed on the rear surface of the second pixel substrate 200 to form an insulating layer, contact/via plugs, and/or bonding pads, and then, the second pixel substrate 200 may be bonded to the front surface of the logic/peripheral substrate 300, on which contact/via plugs and/or bonding pads are formed, through a substrate bonding process.

In addition, the image sensing device may include an I/O pad, which may be used to transmit and receive signals to and from outside the image sensing device and to receive control signals and an electric power. For a 3-stack BSI image sensing device (i.e., with two pixel substrates and one logic/peripheral substrate), since a rear portion of the first pixel substrate 100 has a small thickness, the I/O pad 192 may be formed on the rear surface of the first pixel substrate 100. Referring to FIG. 3, the penetration electrode 194 may be provided and may penetrate the pixel substrate 100 through the rear surface of the pixel substrate 100 and may be connected to a landing pad 247, which may be placed on the second pixel substrate 200.

The insulating layer 195 may be provided between the penetration electrode 194 and the substrate 100 to electrically separate the substrate 100 from the penetration electrode 194. The penetration electrode 194 may be a via. The I/O pad 192 may be provided on the penetration electrode 194, and the rear surface of the substrate 100 may be protected by the second insulating layer 178 and/or a passivation layer 176. In some embodiments, the second insulating layer 178 and/or the passivation layer 176 may be formed of or include the same material as a layer of the micro lens.

In addition, the I/O pad 192 may be connected to the device of the logic/peripheral substrate 300 through the penetration electrode 260, which may be formed in the second pixel substrate 200, a vertical line 249, and a horizontal line 248. In some embodiments, to reduce a resistance and increase a signal transfer speed, the vertical and horizontal lines, which may be connected to each other, may be provided in plurality.

FIG. 3 illustrates a stack image sensing device, in which two pixel substrates are bonded to each other in a face-to-face manner and one logic/peripheral substrate is bonded in a front-to-rear manner. In some embodiments, since the dual vertical transfer gate 120 including the first insulating pattern 125 between the gate poles is used, the interconnection structure may be simplified, and a negative charge transfer efficiency may be improved. In some embodiments, the number of the interconnection line of the first pixel substrate 100 may be one, and the number of the interconnection lines of the second pixel substrate 200 may be two.

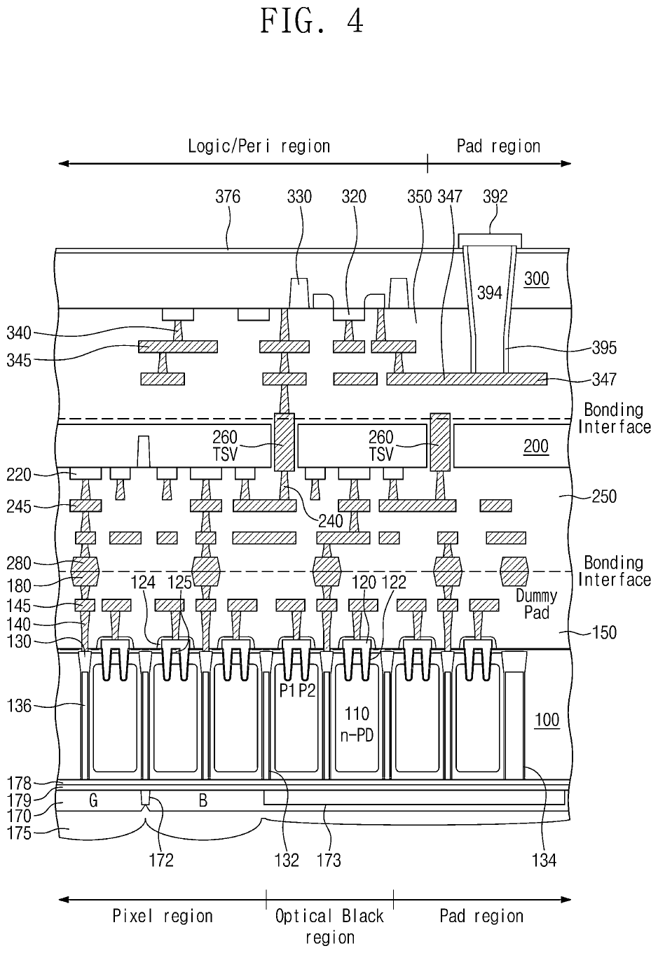

FIG. 4 is a sectional view illustrating a 3-stack CIS device according to some embodiments of the inventive concepts.

Referring to FIG. 4, similar to embodiments according to FIG. 3, in some embodiments the first pixel substrate 100 and the second pixel substrate 200 may be bonded to each other in a face-to-face wafer bonding manner, and in such embodiments, a bonding interface may be formed therebetween. The second pixel substrate 200 may be bonded to the logic/peripheral substrate 300 in such a way that the front surface of the logic/peripheral substrate 300 is bonded to the rear surface of the second pixel substrate 200, and in this case, another bonding interface may be formed therebetween.

In addition, the rear surface of the first pixel substrate 100 with the photodiode and the transfer gate 120 may be used as a light-receiving part, and various optical elements, such as a color filter and a micro lens, may be provided on the rear surface of the first pixel substrate 100.

The transfer gate 120 including a pair of poles P, which may be extended to the n-type region n-PD or 110 of the photodiode, may be formed in the first pixel substrate 100, and the first insulating pattern 125 may be formed on the first pixel substrate 100 and between the paired poles. Except for the afore-described features, the isolation structure, the interconnection structure, and the bonding pad 180 may have substantially the same features as in FIG. 3.

An analog pixel circuit, such as the source follower transistor, the reset transistor, and the selection transistor, may be formed on the second pixel substrate 200 and may be connected to a device of the first pixel substrate 100 through the bonding pads 280 and 180. For example, the floating diffusion region of the first pixel substrate 100 may be connected to the gate 220 of the source follower transistor of the second pixel substrate 200. The analog device of the second pixel substrate 200 may be connected to one or more pixels on the first pixel substrate 100.

In addition, the second pixel substrate 200 may include the penetration electrode 260, which may extend through the second pixel substrate 200 and may be used to connect the first pixel substrate 100 to the logic/peripheral substrate 300. The interconnection structure on the second pixel substrate 200, the formation of the penetration electrode 260, and the wafer bonding process with the first pixel substrate 100 may be substantially the same as those in the embodiment of FIG. 3.

The logic/peripheral substrate 300 may include a peripheral circuit, which may be used to drive the pixel circuit, and a logic circuit, which may be used to process an image signal.

The logic/peripheral substrate 300 in embodiments according to FIG. 4 may include a pad region, in contrast to embodiments according to FIG. 3. In greater detail, in some embodiments an opening may be formed and may penetrate the logic/peripheral substrate 300 through the rear surface of the logic/peripheral substrate 300, an insulating layer for electric isolation of the logic/peripheral substrate 300 may be formed in the opening, and then, a penetration electrode 394 may be formed to fill the opening. A passivation layer 376 may be formed on the rear surface of the substrate, a portion of the passivation layer 376 may be removed to expose the penetration electrode 394, and then, an I/O pad 392 may be formed to cover the penetration electrode 394. In some embodiments, to facilitate the formation of the penetration electrode 394 of the logic/peripheral substrate 300, the logic/peripheral substrate 300 may be thinned, and then, a penetration electrode process may be performed.

In embodiments where, as shown in FIG. 4, the pad region is formed on the rear surface of the logic/peripheral substrate 300, it may be directly connected to a power supplying part, which may be placed on the logic/peripheral substrate 300, through the landing pad 347, and an image signal may be processed by an image processing unit (ISP) and may be directly sent to an application process (AP) or a central processing unit (CPU). Since, as described above, the interconnection or routing structure may be relatively simple and a large area of a pixel substrate may be used, it may be possible to increase (e.g., easily increase) an integration density of the device.

Other features of the logic/peripheral substrate 300 of FIG. 4 (e.g., related to the formation of the device on the substrate, the formation of the interconnection line and the contact/via plug, and the bonding of the second pixel substrate 200 in the front-to-rear bonding manner) may be substantially the same as those according to FIG. 3.

In the embodiments according to FIG. 4, the layer number of the interconnection lines formed on the first pixel substrate 100 may be one or two, and the layer number of the interconnection lines formed on the second pixel substrate 200 may be two or three.

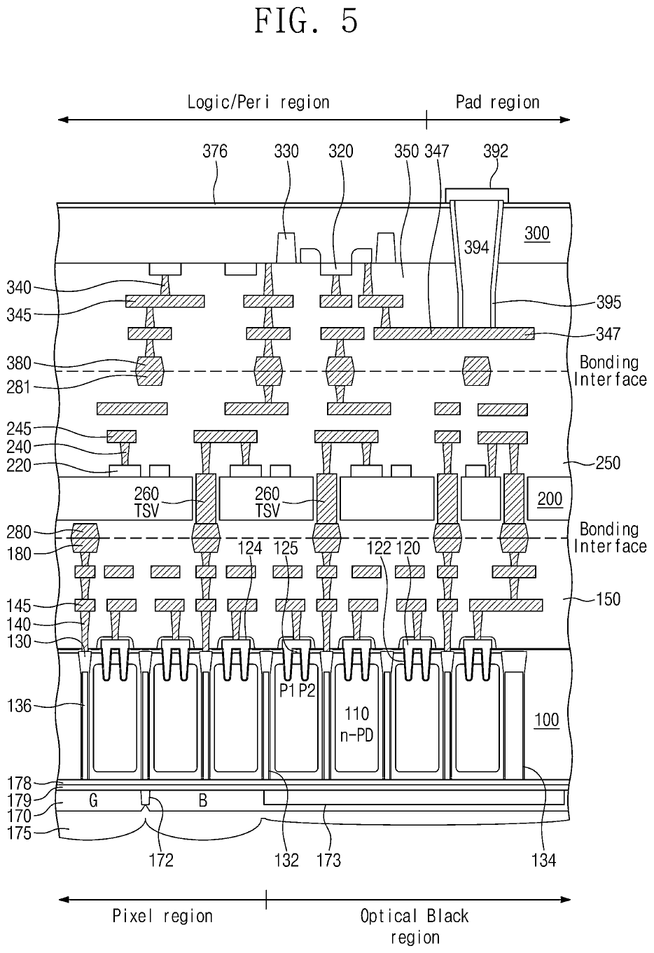

FIG. 5 is a sectional view illustrating a 3 stack CIS device according to some embodiments of the inventive concepts.

In embodiments according to FIG. 5, the first pixel substrate 100, the second pixel substrate 200, and the logic/peripheral substrate 300 may be bonded to each other to form two bonding interfaces, as shown in FIG. 5. The transfer gate 120, which may include a pair of poles P1 and P2 extended to the n-type region n-PD or 110 of the photodiode in the first pixel substrate 100, may be formed on the front surface of the first pixel substrate 100, and the first insulating pattern 125 may be formed on the first pixel substrate 100 and between the paired poles P1 and P2.

Light may be incident into the rear surface of the substrate 100, and a light-receiving element, such as a color filter and a micro lens, may be formed on the rear surface of the substrate 100.

An analog pixel circuit, such as the source follower transistor, the reset transistor, and the selection transistor, may be formed on the second pixel substrate 200. The analog pixel circuit may be connected to a device of the first pixel substrate 100 through the bonding pads 280 and 180. For example, the floating diffusion region in the first pixel substrate 100 may be connected to the gate 220 of the source follower transistor of the second pixel substrate 200. The analog device of the second pixel substrate 200 may be connected to one or more pixels on the first pixel substrate 100. In addition, the second pixel substrate 200 may include the penetration electrode 260, which may penetrate or extend through the second pixel substrate 200 and may be used to connect the first pixel substrate 100 to the logic/peripheral substrate 300.

In contrast to the embodiments according to FIG. 4, the front surface of the first pixel substrate 100 and the rear surface of the second pixel substrate 200 in the embodiments according to FIG. 5 may be bonded to form a bonding interface. The second pixel substrate 200 and the logic/peripheral substrate 300 may be bonded to each other in a face-to-face manner to form a bonding interface.

In the embodiments according to FIG. 5, a pad region may be provided on the rear surface of the logic/peripheral substrate 300. An opening may be formed and may penetrate the logic/peripheral substrate 300, an insulating layer 395 may be formed to cover an inner side surface of the opening, and then, the penetration electrode 394 may be formed to fill the opening with the insulating layer 395. In some embodiments, a chemical-mechanical polishing (CMP) may be performed to thin the logic/peripheral substrate 300, and then, the penetration electrode 394 may be formed in the thinned logic/peripheral substrate 300.

Other features (e.g., related to the disposition of the interconnection lines in the first and second pixel substrates 100 and 200, the formation of the penetration electrode 260 of the second pixel substrate 200, the formation of the insulating layer on the substrate surface, and the connection and sharing of the pixel of the first pixel substrate 100 and the analog circuit of the second pixel substrate 200) may be substantially the same as those in the embodiments according to FIGS. 3 and 4.

Meanwhile, FIG. 5 illustrates an example, in which the interconnection lines on the first pixel substrate 100 are formed to have a double-layered structure, but in some embodiments, the interconnection lines may be formed to have a single-layered structure.

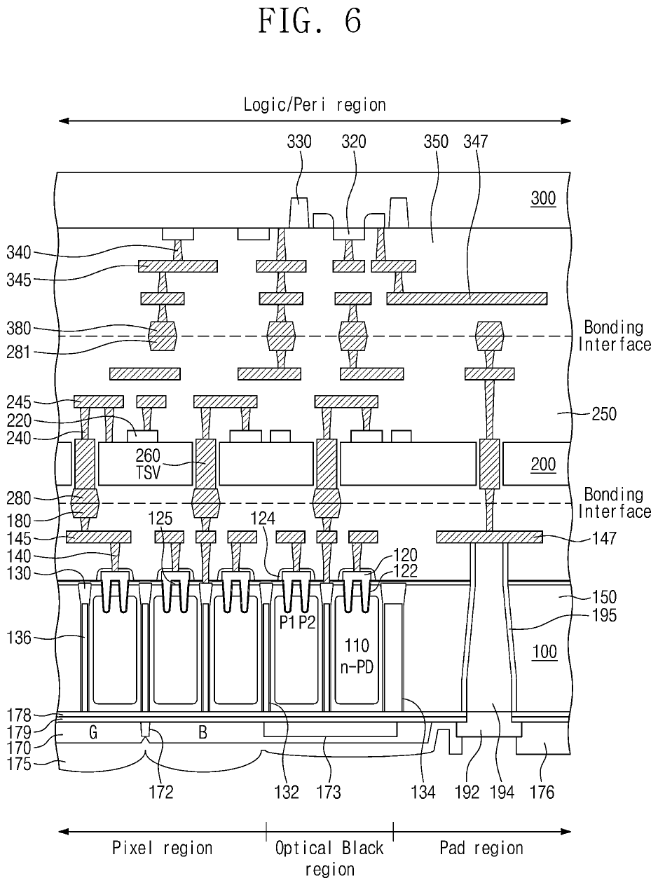

FIG. 6 is a sectional view illustrating a 3-stack CIS device according to some embodiments of the inventive concepts. Devices, which are provided on the first pixel substrate 100, the second pixel substrate 200, and the logic/peripheral substrate 300, and an interconnection structure thereof may be substantially the same as those in the embodiments according to FIG. 5.

The embodiments according to FIG. 6 may differ from the embodiments according to FIG. 5 in that the pad region may be formed on the rear surface of the first pixel substrate 100. For this, an opening may be formed and may penetrate the first pixel substrate 100 through a rear surface of the first pixel substrate 100, the insulating layer 195 may be formed to cover the opening, and then, the penetration electrode 194 may be formed in the opening with the insulating layer 195. In this case, the penetration electrode 194 may be connected to a device of the logic/peripheral substrate 300 through a landing pad 147 and the penetration electrode 260, which is formed in the second pixel substrate 200.

Hereinafter, a device, which includes a first insulating pattern and a vertical transfer gate, a substrate therewith, and a method of fabricating a stack image sensing device therewith will be described below.

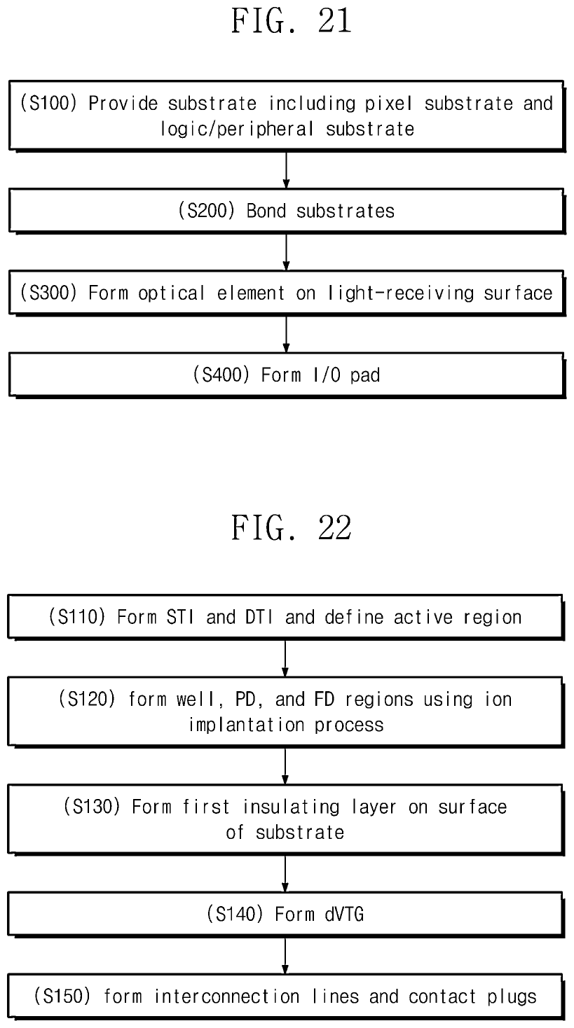

FIG. 21 is a flow chart illustrating a process of fabricating a CIS device, according to some embodiments of the inventive concepts. The process of fabricating the CIS device may include providing a substrate structure including a pixel substrate and a logic/peripheral substrate (in S100), bonding the substrates to each other (in S200), forming an optical element on a light-receiving surface (in S300), and forming an I/O pad (in S400).

FIG. 22 is a flow chart illustrating a process of fabricating a substrate, which includes a dual vertical transfer gate and a first insulating pattern, according to some embodiments of the inventive concepts. The process may be performed as a part of the operation S100 of FIG. 21. In some embodiments, the process of fabricating the substrate 100, which includes a dual vertical transfer gate and a first insulating pattern, may include forming an isolation structure (e.g., a shallow trench isolation (STI) or a deep trench isolation (DTI) structure) in the substrate 100 to define an active region (in S110), forming a well region, an n-type region n-PD, a p-type region, and a floating diffusion region FD using an ion doping process (e.g., an ion implantation process) (in S120), forming a first insulating layer on a surface of the substrate (in S130), forming a dual vertical transfer gate (dVTG) in the substrate (in S140), and forming interconnection lines and contact/via plugs (in S150). The operation of S150 may include forming a bonding pad and an interlayer insulating layer.

The bonding of the substrates (in S200) may be classified into a method (hereinafter, a 2 substrate stacking method) of bonding one pixel substrate to one logic/peripheral substrate and a method (hereinafter, 3 substrate stacking method) of bonding two pixel substrates to one logic/peripheral substrate.

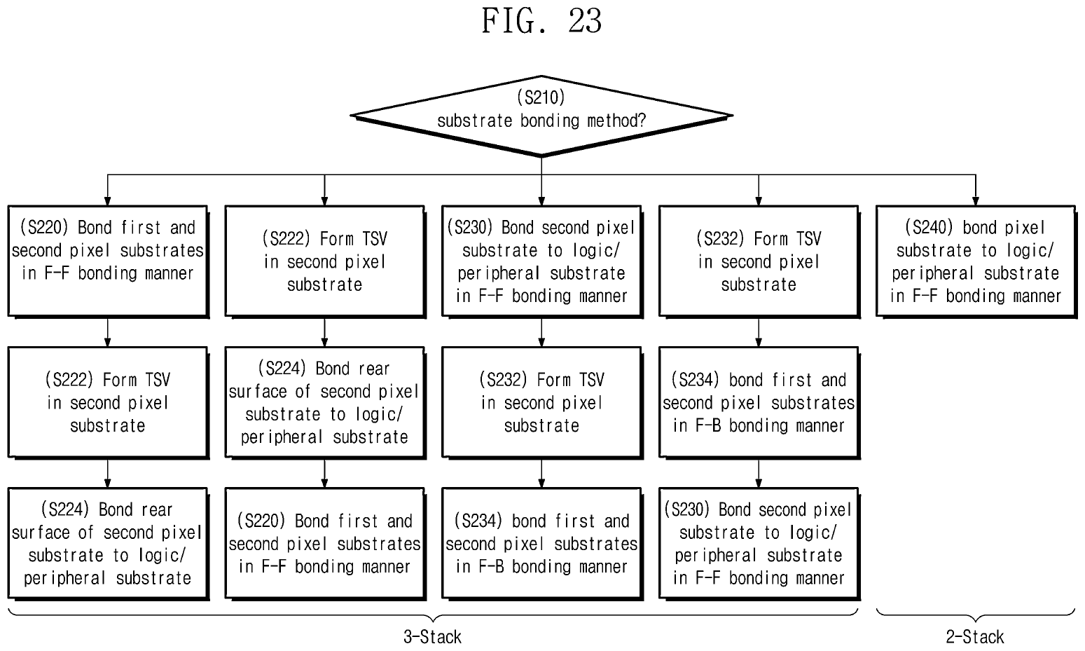

Referring to FIG. 23, a 3 substrate stacking method, which is shown in the first column, may include an operation (S220) of bonding a first pixel substrate to a second pixel substrate in a face-to-face bonding manner, an operation (S222) of forming a penetration electrode in the second pixel substrate, and an operation(S224) of bonding a rear surface of the second pixel substrate to a logic/peripheral substrate. When the operation (S222) is performed, a CMP process may be performed on the second pixel substrate to reduce a thickness of the substrate, and then, a process of forming a penetration electrode may be performed.

A 3 substrate stacking method, which is shown in the second column of FIG. 23, may include the operation (S222) of forming the penetration electrode in the second pixel substrate, the operation (S224) of bonding the rear surface of the second pixel substrate to the logic/peripheral substrate, and the operation (S220) of bonding the first pixel substrate to the second pixel substrate in a face-to-face bonding manner.

A 3 substrate stacking method, which is shown in the third column of FIG. 23, may include an operation (S230) of bonding the second pixel substrate to the logic/peripheral substrate in a face-to-face bonding manner, an operation (S232) of forming the penetration electrode in the second pixel substrate, and an operation (S234) of bonding the first pixel substrate to the second pixel substrate in a front-to-rear bonding manner. When the operation (S232) is performed, a CMP process may be performed on the second pixel substrate to reduce a thickness of the substrate, and then, a process of forming the penetration electrode may be performed.

A 3 substrate stacking method, which is shown in the fourth column of FIG. 23, may include the operation (S232) of forming the penetration electrode in the second pixel substrate, the operation (S234) of bonding the front surface of the first pixel substrate to the rear surface of the second pixel substrate, and the operation (S230) of bonding the second pixel substrate to the logic/peripheral substrate in a face-to-face bonding manner.

A 2 substrate stacking method, which is shown in the fifth column of FIG. 23, may include an operation (S240) of bonding the pixel substrate to the logic/peripheral substrate in a face-to-face bonding manner.

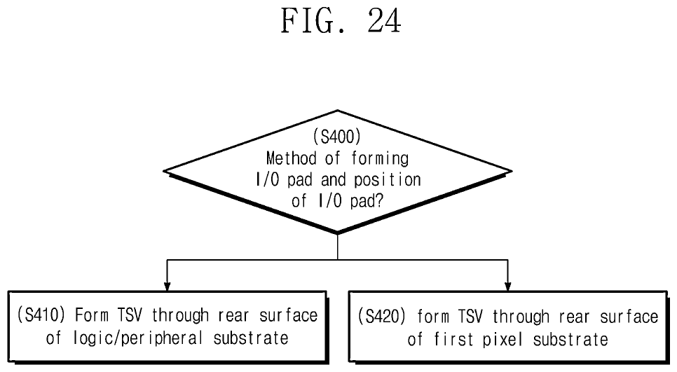

FIG. 24 is a flow chart illustrating a process flow, depending on a position of an I/O pad and a method of forming the I/O pad. In the operation (S400) of forming the I/O pad, the method of forming the I/O pad may be determined by which side of the outermost one of the stacked substrates the I/O pad is formed on. Referring to FIG. 24, the method of forming the I/O pad (in S400) may include a method of forming a pad region in the logic/peripheral substrate (in S410) and forming a pad region on the rear surface of the pixel substrate or the first pixel substrate (in S420). In the case where the pad region is formed in the logic/peripheral substrate (in S410), a penetration electrode may be formed through the rear surface of the logic/peripheral substrate. In the case where the pad region is formed in the first pixel substrate (in S420), the penetration electrode may be formed through the rear surface of the first substrate or the first pixel substrate.

Next, a method of fabricating a 2-stack image sensing device, which may be formed by bonding one pixel substrate to one logic/peripheral substrate, will be described below.

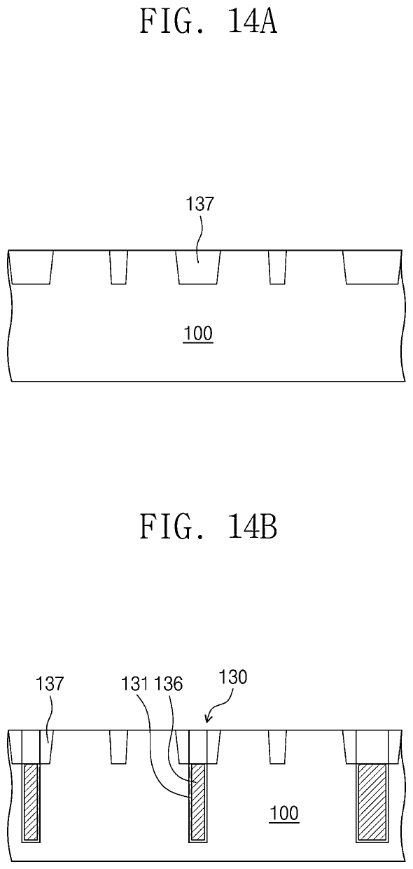

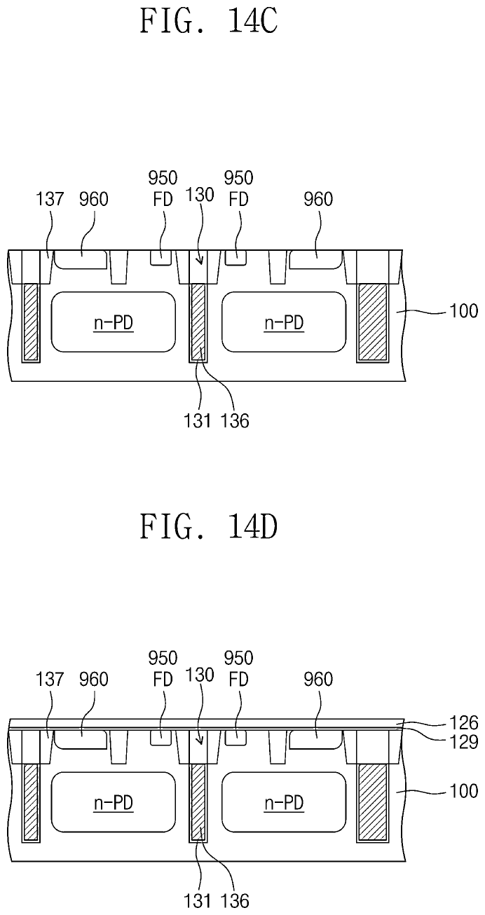

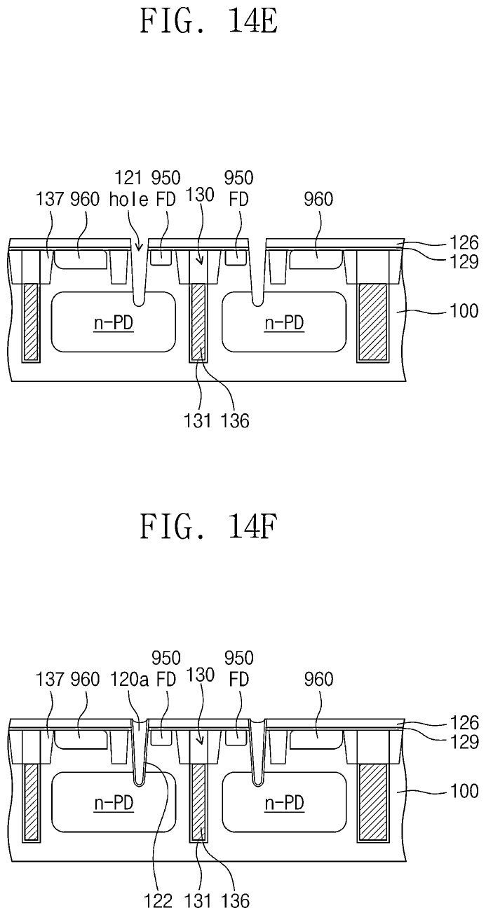

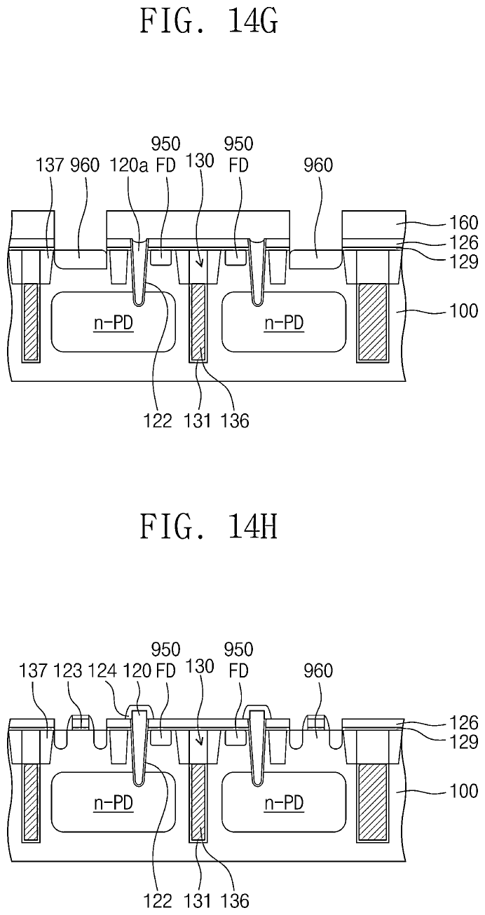

FIGS. 14A to 141 are sectional views illustrating a process of fabricating a first substrate including a photodiode, a first insulating layer, and a vertical transfer gate, according to an embodiment of the inventive concept. FIGS. 14A to 141 are sectional views, which are taken in the same direction as in FIG. 12B. Here, the first insulating layer may include a first insulating pattern, which is formed on the substrate and between the poles P1 and P2 of the dual vertical transfer gate.

Referring to FIG. 14A, an isolation structure may be formed in a substrate to define an active region. The substrate 100 may be a silicon substrate or a compound semiconductor substrate, which may be formed of, for example, indium phosphide (InP), gallium arsenide (GaAs), silicon germanium (SiGe), indium arsenide (InAs), silicon carbide (SiC), or other suitable compound semiconductor material. The silicon substrate may include a bulk silicon layer or a layer that is provided to have a silicon-on-insulator (SOI) structure.

The substrate 100 may be an n- or p-type substrate, which may contain one or more dopants. In some embodiments, the substrate 100 may be a p-type substrate, in which dopants of boron (B), aluminum (Al), or indium (In) are injected.

An isolation structure 137 may include a shallow trench isolation (STI) pattern and may be formed by forming an opening through a photolithography technology and filling the opening with an insulating material (e.g., SiO₂, SiₓN_{y}, and composite materials).

As shown in FIG. 14B, a deep trench may be formed by, for example, a dry etching process, and may be filled with an insulating material to form the isolation structure 130 separating pixel regions from each other. In some embodiments, the conductive layer 136 may be formed and may apply a bias to the isolation structure 130. The conductive material may include polysilicon or tungsten. To electrically isolate the conductive material, the insulating layer 131 may be formed in the trench.

As shown in FIG. 14C, a well region 960, a floating diffusion region FD or 950, and the n-type region n-PD of the photodiode may be formed by injecting ions into the substrate 100. In addition, p dopants (e.g., N, P, or As) may be injected into the p-type region to create a positional variation in doping concentration of the p-type region. For example, the p dopants may be injected into a region around the isolation structure 130 to increase a doping concentration of p-type dopants in a region around the n-PD region. In some embodiments, a pin-type photodiode may be formed by increasing a doping concentration of the p-type dopants at the surface of the substrate 100, and a ground node (GND) may be formed by a similar method.

As shown in FIG. 14D, the first insulating layer 126 may be formed on the substrate 100. The first insulating layer 126 may include a single layer and a composite layer, which may be formed of at least one of SiₓN_{y}, SiON, SiONC, SiO₂, and SiOC. In some embodiments, the first insulating layer 126 may be formed of or include at least one of aluminum oxide (Al₂O₃), hafnium oxide (HfO₂), tantalum pentoxide (Ta₂O₅), or titanium oxide (TiO₂).

In some embodiments, a deposition process may be used to form the first insulating layer 126 on the substrate 100. The deposition process may include, for example, a chemical vapor deposition (CVD) process.

In the case where a silicon nitride layer is used as the first insulating layer 126, a liner 129 may be deposited in advance to prevent a delamination issue. In some embodiments, a silicon oxide layer may be used as the liner 129.

Referring to FIG. 14E, an opening 121 may be formed in the substrate 100. In some embodiments, the number of the openings 121 per gate may be two. The formation of the opening may include forming photoresist patterns on the substrate and performing a dry etching process on the substrate using the photoresist patterns. In some embodiments, a plasma-assist dry etching process may be used to increase the anisotropy in the dry etching process.

Referring to FIG. 14F, the gate insulating layer 122 may be formed in the opening 121. The gate insulating layer 122 may be a silicon oxide layer, a silicon nitride layer, and a composite layer thereof and may be formed by an atomic layer deposition (ALD) or oxidizing the exposed surface of the opening. In this case, the gate insulating layer 122 may have a superior quality (e.g., density), even when the gate insulating layer 122 has a small thickness.

In some embodiments, the process may be modified to improve quality of the gate insulating layer 122 and alter an energy band gap of the gate insulating layer 122. For example, the gate insulating layer 122 may be doped with an element, such as nitrogen, or may be formed to further include another deposition layer.

In some embodiments, an annealing process may be further performed, before or after at least one of the deposition or ion-implantation processes, which may be performed as a part of the fabrication process.

After the formation of the gate insulating layer 122, a first polysilicon 120a may be formed to fill the opening 121.

Referring to FIG. 14G, a photomask 160 may be formed, and the first insulating layer 126 may be removed partially using the photomask 160 as a patterning mask.

Referring to FIG. 14H, a gate insulating layer 123 may be formed on a region exposed by the patterning process using the photomask 160, and then, a second poly-silicon layer may be formed on the gate insulating layer 123. Next, a gate may be formed by patterning the second poly-silicon layer and the gate insulating layer 123. The gate may include the dual vertical transfer gate 120 and a gate of other analog circuit, such as the source follower transistor SF and the reset transistor RG.

In some embodiments, a spacer 124 may be formed optionally around and on the gate.

Referring to FIG. 14I, a PD and a transistor may be formed in and on the substrate 100, the contact 140 and the interconnection line 145 may be formed, and an interlayer insulating layer for electric isolation may be formed to protect a conductive layer. The bonding pad 180 may be formed on the interlayer insulating layer.

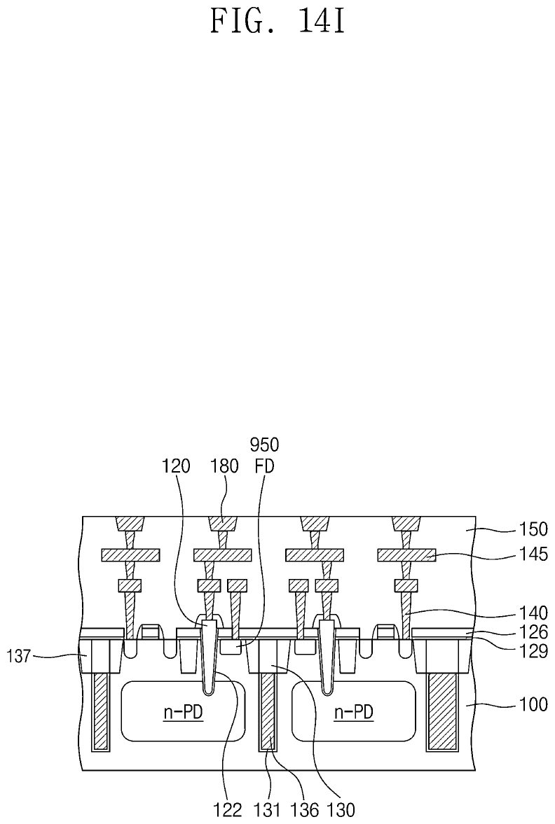

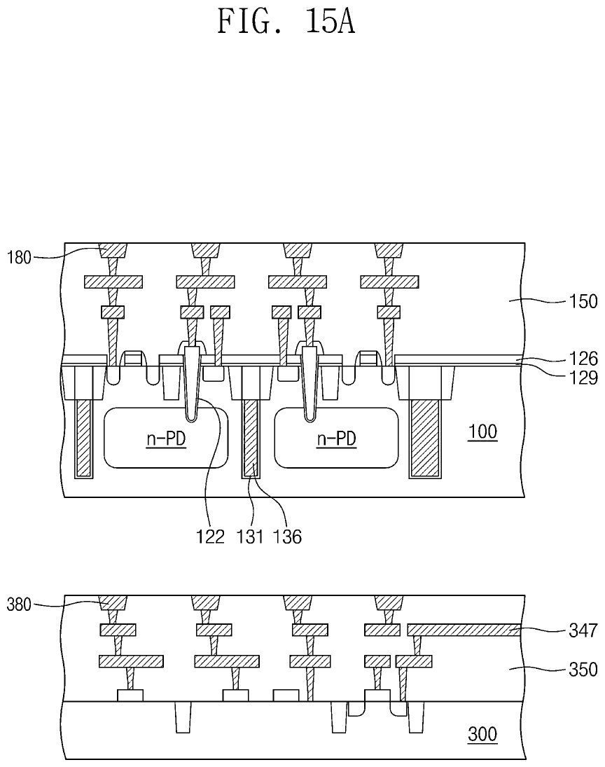

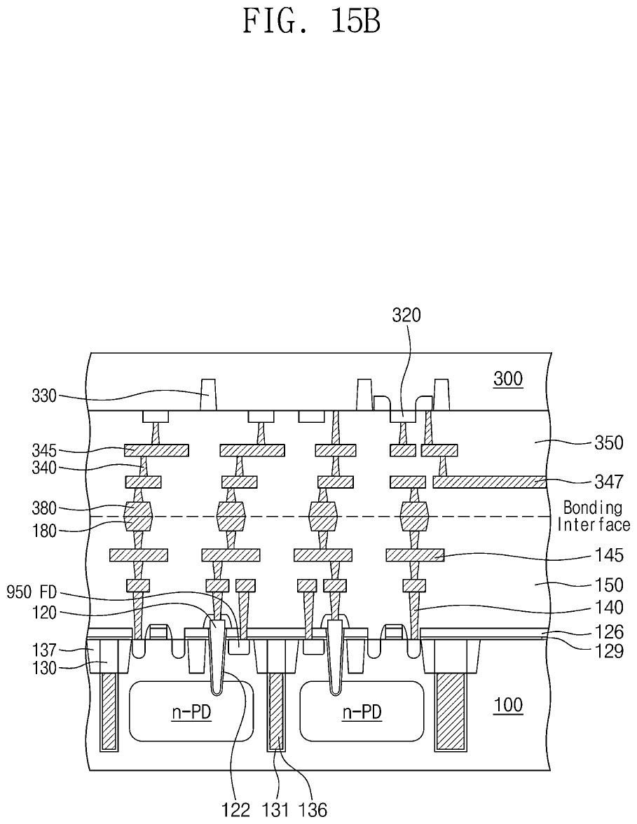

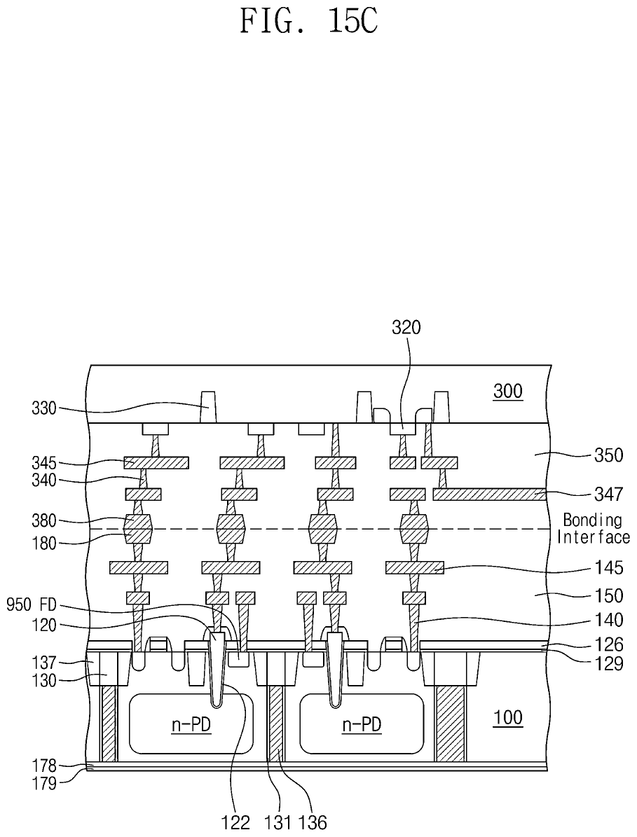

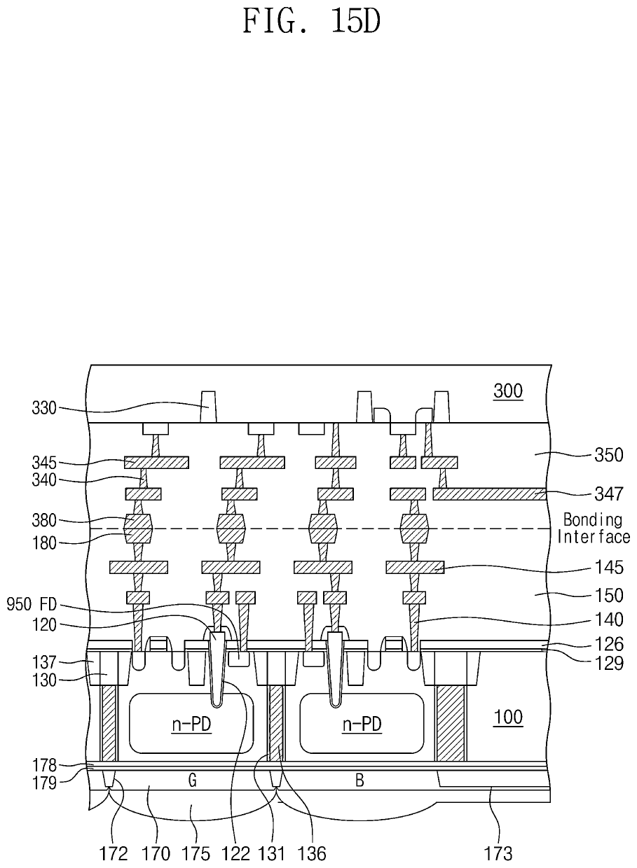

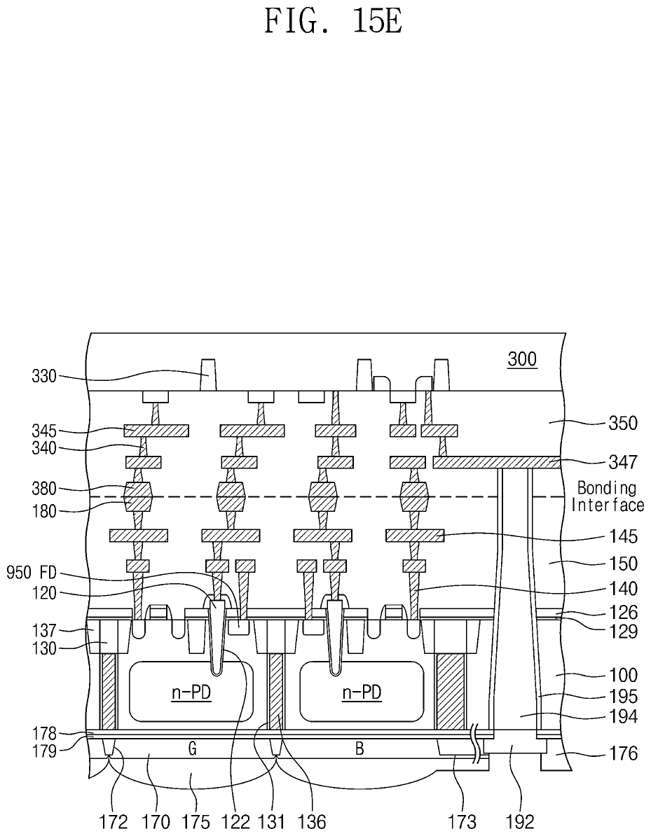

FIGS. 15A to 15E illustrate a method of fabricating a 2-stack image sensing device, according to some embodiments of the inventive concept, and in particular, a process of bonding the pixel substrate 100 and the logic/peripheral substrate 300 and forming the I/O pad.

Referring to FIG. 15A, the pixel substrate 100 and the logic/peripheral substrate 300 may be provided, respectively. The logic/peripheral substrate 300 may include the gate 320, the contacts 340, and the interconnection lines 345, and may further include the bonding pad 380 provided on the interlayer insulating layer 350.

The logic/peripheral substrate 300 may be formed separately by a process that is distinct from the pixel substrate 100. In some embodiments, a silicon gate transistor or a metal gate transistor may be formed on the logic/peripheral substrate 300, and it may be a planar transistor or a FinFET transistor.

Referring to FIG. 15B, the pixel substrate 100 and the logic/peripheral substrate 300 may be placed or aligned in such a way that the front surface of the pixel substrate 100 faces the front surface of the logic/peripheral substrate 300. Thereafter, the pixel substrate 100 and the logic/peripheral substrate 300 may be bonded to each other through a wafer bonding process. At a bonding interface between the pixel substrate 100 and the logic/peripheral substrate 300, the bonding pads 180 and 380 may be aligned and bonded to each other.

Referring to FIG. 15C, a rear portion of the pixel substrate 100 may be partially removed, and then, the second insulating layer 178 may be formed on a rear surface of the pixel substrate 100. The second insulating layer 178 may include a hafnium oxide layer, a tantalum oxide layer, and/or an aluminum oxide layer and may be used to prevent negative charges, which are generated in the photodiode, from being trapped or lost on the removed substrate. The anti-reflection layer 179 may be formed on the second insulating layer 178.

In some embodiments, the pixel substrate 100 may be thinned by performing a chemical-mechanical polishing (CMP) on the rear surface of the pixel substrate 100. The process of thinning the pixel substrate 100 may be performed to expose the isolation structure 130.

Referring to FIG. 15D, an insulating layer may be formed on the rear surface of the pixel substrate 100, and then, the grid 172, the color filters 170, the light blocking member 173, and the micro lens 175 may be formed thereon. The grid 172 may be formed in the pixel array and may prevent a crosstalk issue from occurring between neighboring pixels. The light blocking member 173 may be formed in an optical black region OB. In the pixel array, the grid 172 and the light blocking member 173 may be formed of or include the same material and may be formed together through a single process.

Referring to FIG. 15E, an opening may be formed and may penetrate the pixel substrate 100 through the rear surface of the pixel substrate 100 and extend to the landing pad 347 on the logic/peripheral substrate 300. Next, the insulating layer 195 may be deposited to cover the opening, and then, the penetration electrode 194, which may be electrically disconnected from the pixel substrate 100 by the insulating layer 195, may be formed by filling the opening with a conductive material. The conductive material may include polysilicon or tungsten. The opening may be formed and may penetrate the passivation layer 176 on the rear surface of the pixel substrate 100, and the passivation layer 176 may be formed of or include the same material as a layer of the micro lens. The I/O 192 pad may be formed on an exposed surface of the penetration electrode 194.

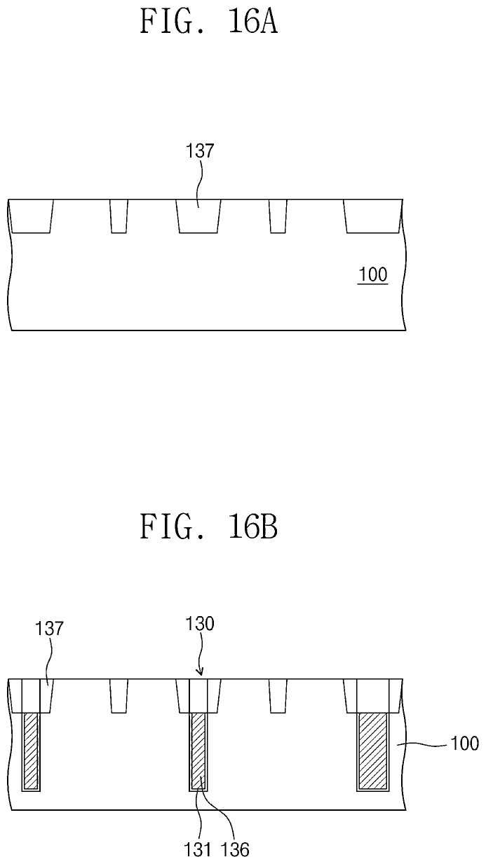

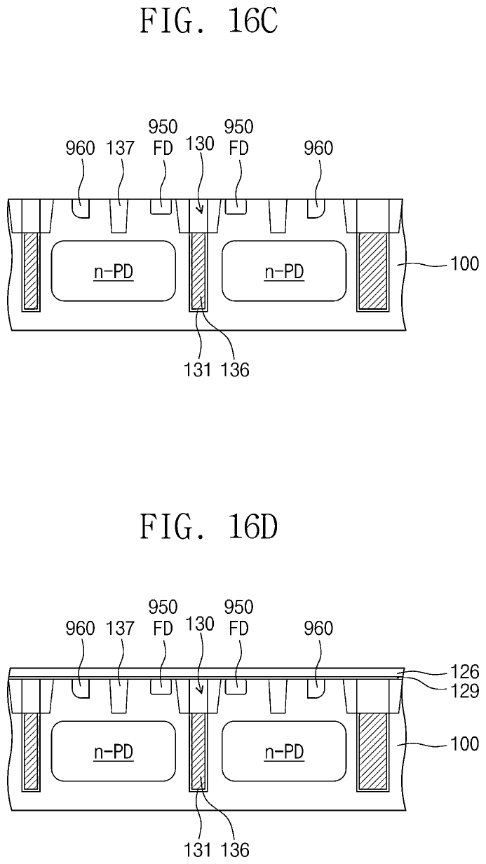

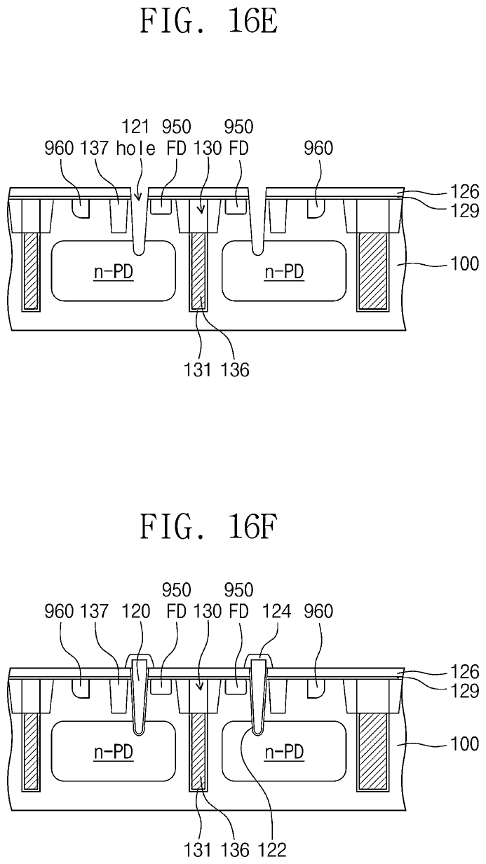

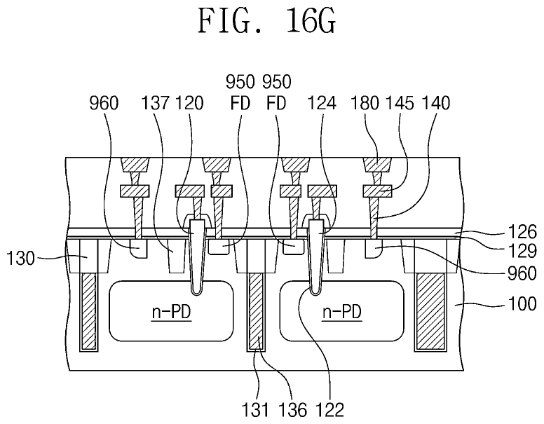

FIGS. 16A to 16G are sectional views illustrating a process of fabricating the first pixel substrate 100, according to some embodiments of the inventive concepts. For example, FIGS. 16A to 16G illustrate a process of fabricating the structure of FIG. 8B or 8C, in which the photodiode PD and the transfer transistor TG are formed on the front surface of the first pixel substrate 100. The source follower transistor SF, the reset transistor RG, and the selection transistor SEL may be formed on a second pixel substrate that may be separately provided, regardless of the first pixel substrate 100. FIGS. 16A to 16G are sectional views, which are taken in the same direction as in FIG. 12B.

Referring to FIG. 16A, the substrate 100 may be provided, and an isolation structure may be formed in the substrate 100 and may define an active region. The substrate 100 may be a silicon substrate or a compound semiconductor substrate, which may be formed of, for example, indium phosphide (InP), gallium arsenide (GaAs), silicon germanium (SiGe), indium arsenide (InAs), silicon carbide (SiC), or other suitable compound semiconductor material. The silicon substrate may include a bulk silicon layer or a layer that is provided to have a silicon-on-insulator (SOI) structure. The dopant injection on the substrate 100 may be performed in the same manner as in FIG. 14A.

The isolation structure 137 may include a shallow trench isolation (STI) pattern and may be formed by forming an opening through a photolithography technology and filling the opening with an insulating material (e.g., SiO₂, SiₓN_{y}, and composite materials).

Referring to FIG. 16B, a deep trench may be formed by, for example, a dry etching process, and then, the isolation structure 130 may be formed by filling the deep trench with an insulating material including a silicon oxide and/or silicon nitride. The pixel regions, which are separated from each other, may be defined by the isolation structure 130. In some embodiments, the conductive layer 136 may be formed and may apply a bias to the isolation structure 139. In some embodiments, the conductive layer 136 and the insulating material may be formed by the method described with reference to FIG. 14B.

As shown in FIG. 16C, the well region 960, the floating diffusion region FD or 950, and the n-type region n-PD of the photodiode may be formed by injecting ions into the substrate 100. In addition, p dopants (e.g., N, P, or As) may be injected into the p-type region to create a positional variation in doping concentration of the p-type region. For example, the p dopants may be injected into a region around the isolation structure 130 to increase a doping concentration of p-type dopants in a region around the n-PD region. In some embodiments, a pin-type photodiode may be formed by increasing a doping concentration of the p-type dopants at the surface of the substrate 100, and a ground node (GND) may be formed by a similar method.

As shown in FIG. 16D, the first insulating layer 126 may be deposited on a surface of the substrate 100. The first insulating layer 126 may include a single layer and a composite layer, which may be formed of at least one of SiₓN_{y}, SiON, SiONC, SiO₂, or SiOC. In some embodiments, the first insulating layer 126 may be formed of or include at least one of aluminum oxide (Al₂O₃), hafnium oxide (HfO₂), tantalum pentoxide (Ta₂O₅), or titanium oxide (TiO₂).

In some embodiments, a deposition process may be used to form the first insulating layer 126 on the substrate 100. The deposition process may include, for example, a chemical vapor deposition (CVD) process.

In the case where a silicon nitride layer is used as the first insulating layer 126, the liner 129 may be deposited in advance to prevent a delamination issue. In some embodiments, a silicon oxide layer may be used as the liner 129.

Referring to FIG. 16E, the opening 121 may be formed in the substrate 100. In some embodiments, the number of the openings 121 per gate may be two. The formation of the opening may include forming photoresist patterns on the substrate and performing a dry etching process on the substrate using the photoresist patterns. In some embodiments, a plasma-assist dry etching process may be used to increase the anisotropy in the dry etching process. The opening may be formed to extend to the n-type region n-PD of the photodiode, which may be formed in the substrate.

Referring to FIG. 16F, the gate insulating layer 122 may be formed in the opening 121. The gate insulating layer 122 may be a silicon oxide layer, a silicon nitride layer, and a composite layer thereof and may be formed by an atomic layer deposition (ALD) or oxidizing the exposed surface of the opening. In this case, the gate insulating layer 122 may have a relatively superior quality (e.g., density), even when the gate insulating layer 122 has a small thickness. After the formation of the gate insulating layer 122, a poly layer may be formed and may fill the opening 121 and may be patterned to form the gate 120. The process of forming the gate 120 may be performed in a 2-step manner by filling the opening 121 with a first polysilicon and then forming and patterning a second polysilicon. During the patterning process, the spacer 124 may be formed optionally around and on the gate.

In the present embodiment, the first insulating layer 126, which is formed on the substrate 100, may be left, and in this case, the left portion of the first insulating layer 126 may be used as an etch stop layer in a subsequent patterning process. Meanwhile, in some embodiments, the first insulating layer 126, which is exposed by the patterning process using the photomask 160, may be removed.

Referring to FIG. 16G, a PD and a transistor may be formed in and on the substrate 100, the contact 140 and the interconnection line 145 may be formed, and an interlayer insulating layer for electric isolation may be formed to protect a conductive layer. The bonding pad 180 may be formed on the interlayer insulating layer. The number of the interconnection layers may be one or two. The bonding pad 180 may be formed of or include copper.

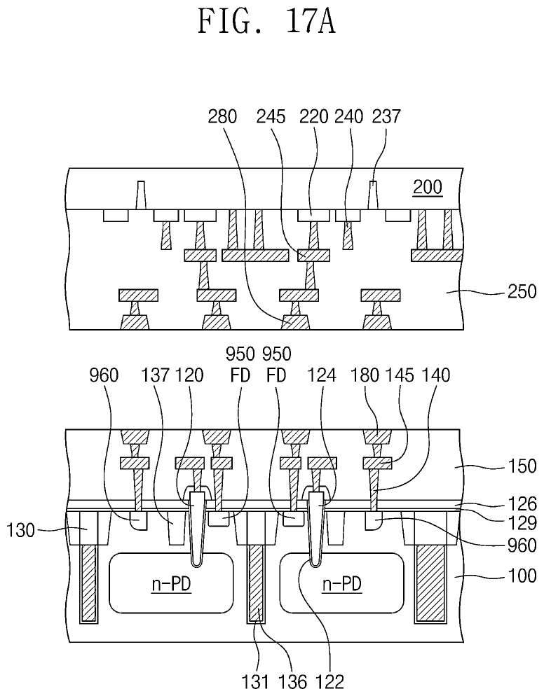

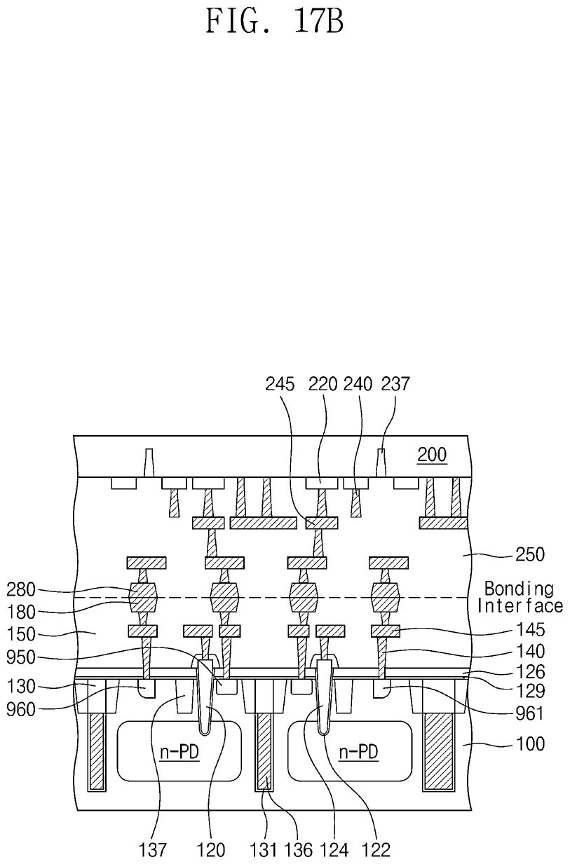

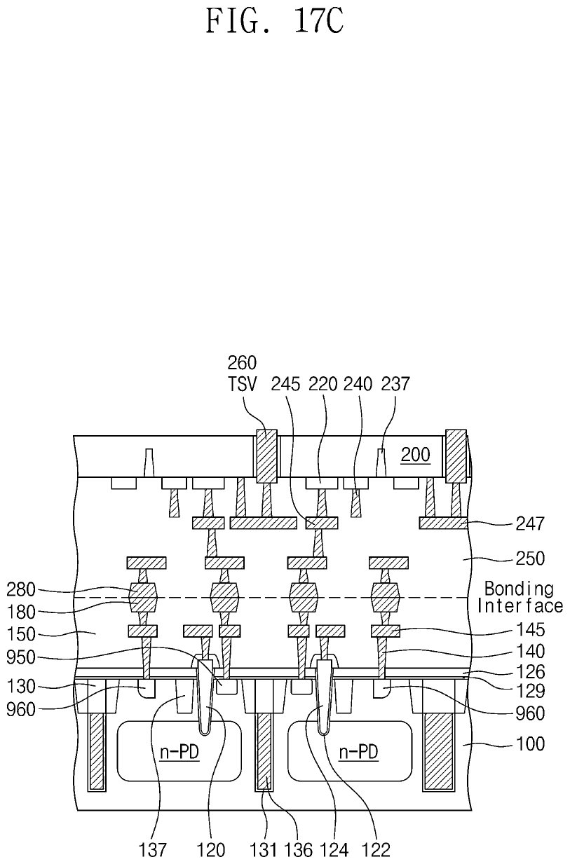

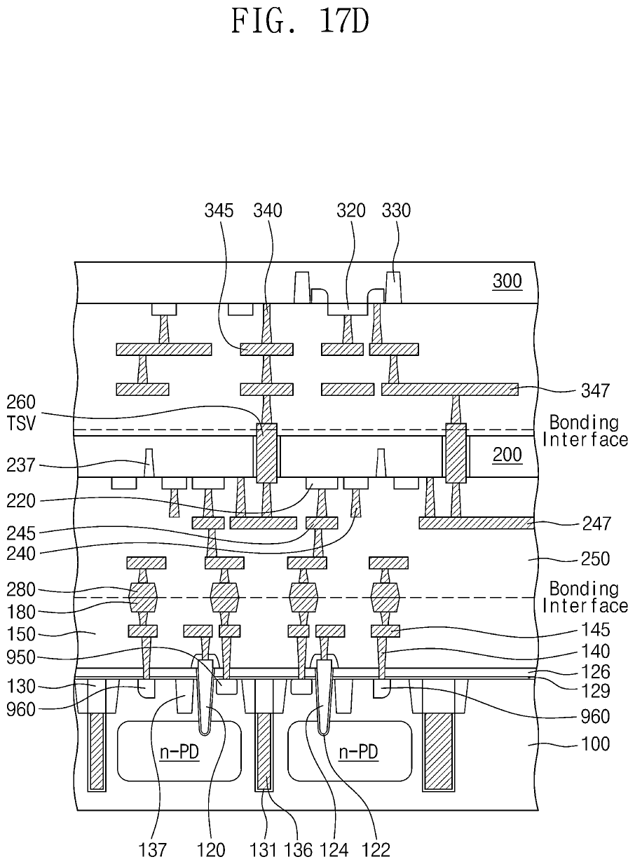

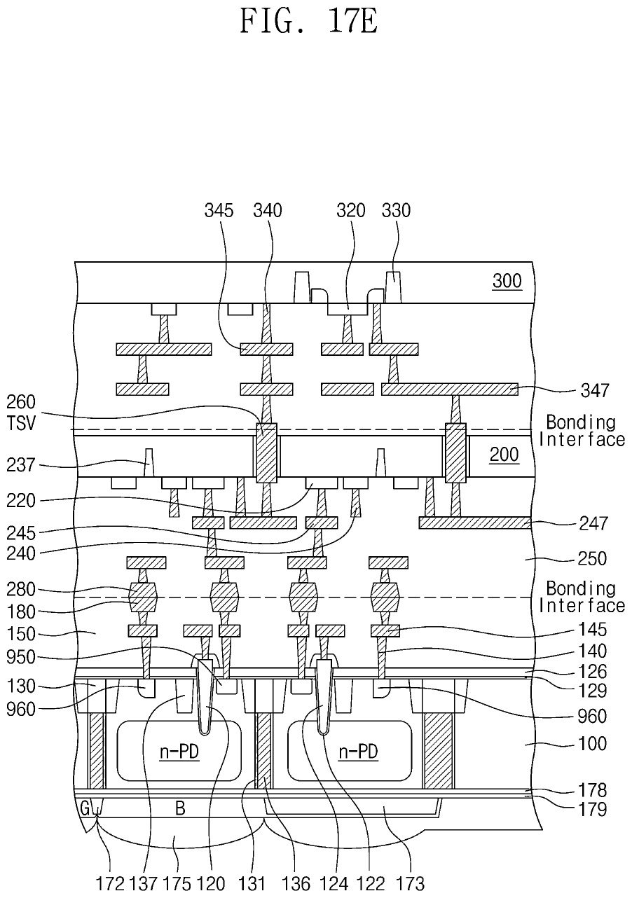

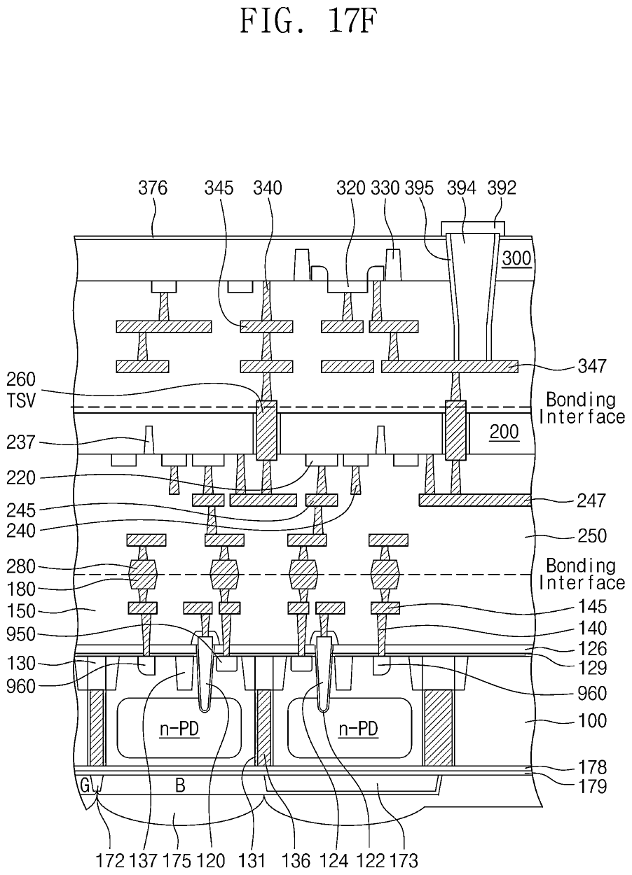

FIGS. 17A to 17F are sectional views illustrating a process of fabricating an image sensing device by stacking two pixel substrates and a logic/peripheral substrate. Hereinafter, a process of bonding the first pixel substrate 100, the second pixel substrate 200, and the logic/peripheral substrate 300 and forming an optical element and an I/O pad will be described with reference to FIGS. 17A to 17F.

Referring to FIG. 17A, the second pixel substrate 200 may be provided independently of the first pixel substrate 100. The second pixel substrate 200 may include active regions, which may be defined by a device isolation region 237, and the source follower transistor SF, the reset transistor RG, and the selection transistor SEL may be formed on the active regions of the second pixel substrate 200.

In some embodiments, a process, which may be separate from that for the first pixel substrate 100, may be performed on the second pixel substrate 200, and in this case, a planar transistor or a FinFET transistor may be formed on the second pixel substrate 200.

A contact 240, an interconnection line 245, and a bonding pad 280, which may be used as an interconnection structure, may be formed on the second pixel substrate 200, and at least one interlayer dielectric layer may be formed to enclose the contact 240, the interconnection line 245, and the bonding pad 280.

Referring to FIG. 17B, the first pixel substrate 100 and the second pixel substrate 200 may be aligned to each other in such a way that the front surface of the first pixel substrate 100 faces the front surface of the second pixel substrate 200 and then, they may be bonded to each other through a wafer bonding process. At an interface of the bonded substrates, the bonding pads 180 and 280 may also be aligned and bonded to each other.

Referring to FIG. 17C, an opening may be formed and may penetrate the second pixel substrate 200 through the rear surface of the second pixel substrate 200 and may extend to an interconnection line on the front surface of the second pixel substrate 200. Next, an insulating layer may be deposited to cover the opening, and then, the penetration electrode 260, which may be electrically disconnected from the second pixel substrate 200 by the insulating layer, may be formed by filling the opening with a conductive material. The conductive material may include polysilicon or tungsten. In the process of forming the opening, a passivation layer may be formed on the rear surface of the second pixel substrate 200, and a portion of the passivation layer may be partially removed. In this case, the penetration electrode 260 may have a shape protruding from the rear surface of the second pixel substrate 200.

Referring to FIG. 17D, the logic/peripheral substrate 300 may be provided through a separate process. The fabrication process of the logic/peripheral substrate 300 may be performed using the method described with reference to FIG. 15A.

The logic/peripheral substrate 300 may be aligned to the second pixel substrate 200 such that the front surface of the logic/peripheral substrate 300 faces the rear surface of the second pixel substrate 200, and they may be bonded to form a three-layered stack.

Referring to FIG. 17E, a rear portion of the first pixel substrate 100 may be partially removed, and then, one or more insulating layers 178 and 179 may be formed on a rear surface of the first pixel substrate 100. The second insulating layer 178 and the anti-reflection layer 179 may be formed to have substantially the same features as those in the embodiment described with reference to FIGS. 15C and 15D.

In some embodiments, the pixel substrate 100 may be thinned by performing a chemical-mechanical polishing (CMP) on the rear surface of the pixel substrate 100. The process of thinning the pixel substrate 100 may be performed to expose the isolation structure 130.

Next, an insulating layer may be formed on the rear surface of the pixel substrate 100, and then, an optical element, such as the grid 172, the color filters 170, the light blocking member 173, and the micro lens 175, may be formed. The optical element may be fabricated by the method described with reference to FIG. 15D.

Referring to FIG. 17F, an opening may be formed to penetrate the logic/peripheral substrate 300 and may extend from the rear surface of the logic/peripheral substrate 300 to the landing pad 347 on the logic/peripheral substrate 300. Next, the insulating layer 395 may be formed to cover the opening, and then, a conductive material may be formed and may fill the opening covered with the insulating layer 395. As a result, the penetration electrode 394, which may be electrically disconnected from the logic/peripheral substrate 300 by the insulating layer 395, may be formed in the opening. The conductive material may include polysilicon or tungsten. The opening may be extended to penetrate the logic/peripheral substrate 300 and the passivation layer 376. The I/O pad 392 may be formed on the exposed penetration electrode 394.

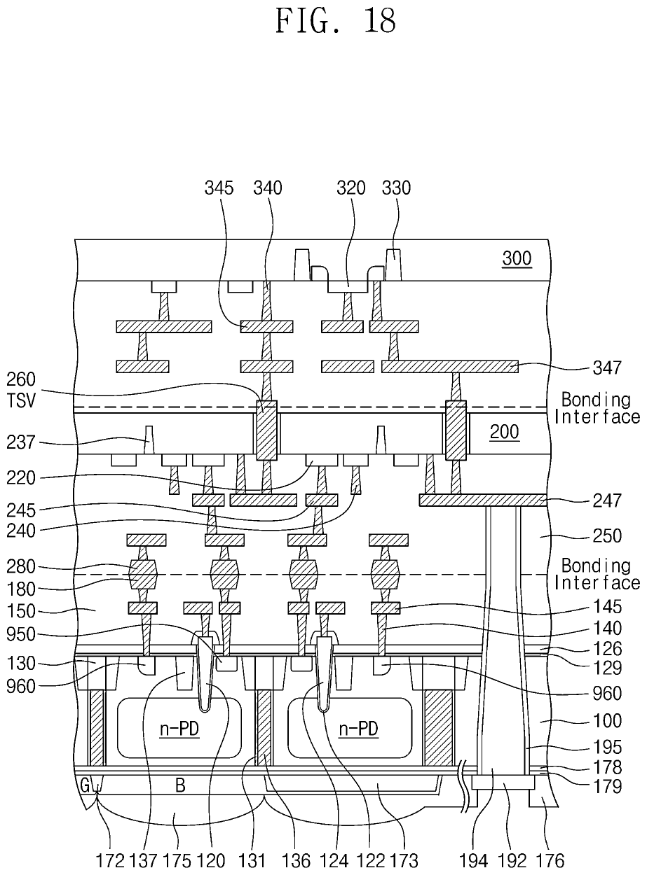

FIG. 18 is a sectional view of a CIS device, which may include a unit pixel circuit and a logic circuit and may be fabricated by a method according to some embodiments of the inventive concepts. Referring to FIG. 18, an opening may be formed and may penetrate the first pixel substrate 100 from the rear surface of the first pixel substrate 100, the insulating layer 195 may be formed to cover the opening, and then, the penetration electrode 194 may be formed in the opening. In some embodiments, the penetration electrode 194, the passivation layer 176, and the I/O pad 192 may be provided to have substantially the same features as those in the embodiments described with reference to FIG. 15.

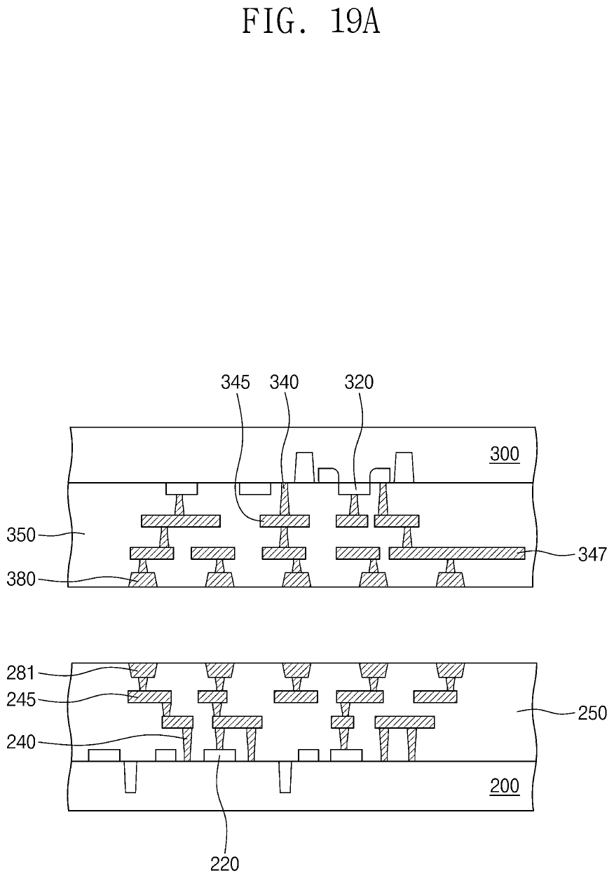

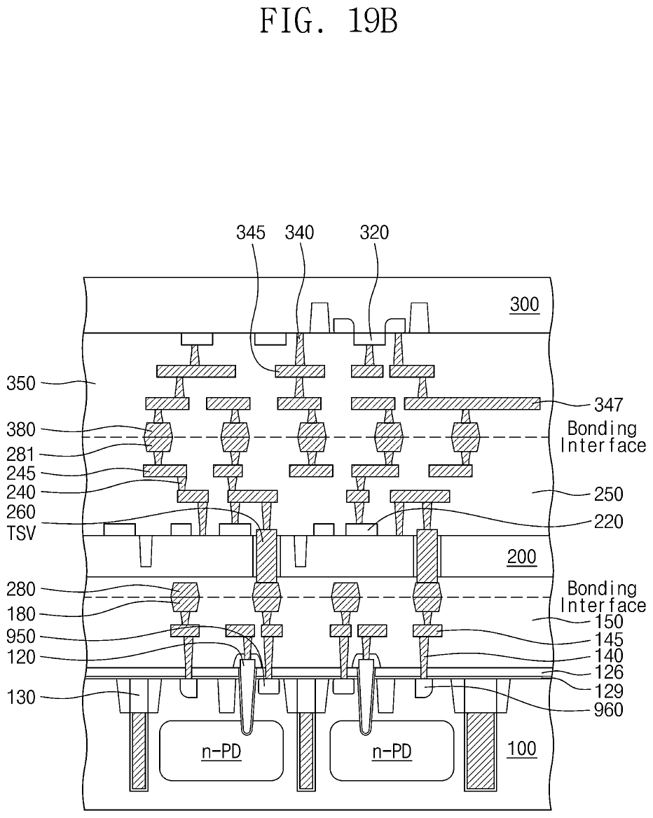

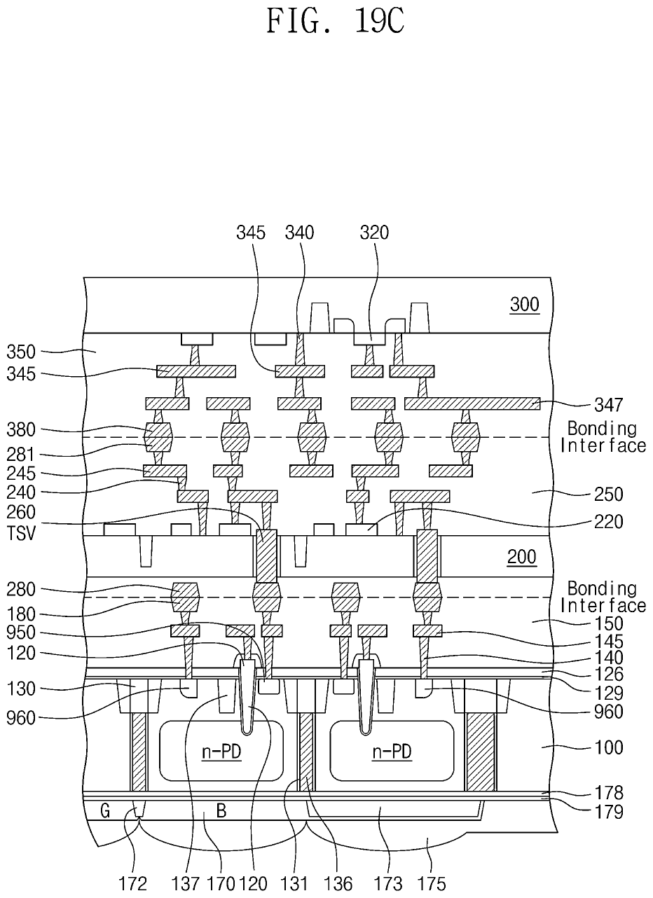

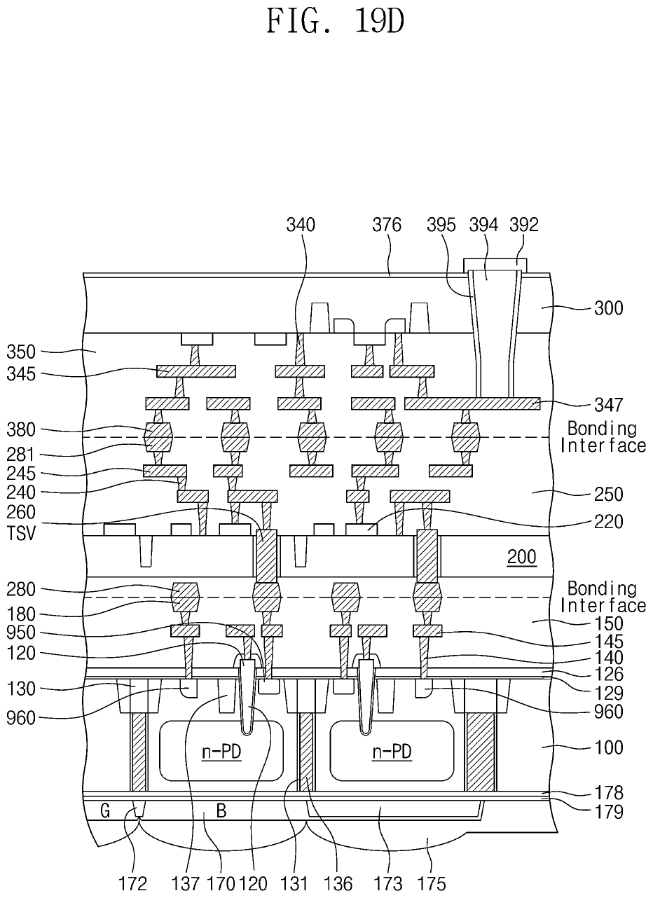

FIGS. 19A to 19D illustrate a method of fabricating an image sensing device by bonding the front surface of the first pixel substrate 100 to the rear surface of the second pixel substrate 200, according to some embodiments of the inventive concepts.

Referring to FIG. 19A, the second pixel substrate 200 and the logic/peripheral substrate 300 may be separately provided. For example, the second pixel substrate 200 may be prepared by the method described with reference to FIG. 17A, and the logic/peripheral substrate 300 may be prepared by the method described with reference to FIG. 15.

Referring to FIG. 19B, the second pixel substrate 200 and the logic/peripheral substrate 300 may be bonded to each other through a wafer bonding process, in which the front surface of the second pixel substrate 200 is placed to face the front surface of the logic/peripheral substrate 300. At a bonding interface between the second pixel substrate 200 and the logic/peripheral substrate 300, a bonding pad 281 of the second pixel substrate 200 may be aligned and bonded to the bonding pad 380 of the logic/peripheral substrate 300.

Referring to FIG. 19B, an opening may be formed to penetrate the second pixel substrate 200 through a rear surface thereof, after bonding the logic/peripheral substrate 300 to the second pixel substrate 200 in a front-to-front (F-F) bonding manner as shown in FIG. 19A. Next, an insulating may be formed in the opening, and then, the penetration electrode 260 may be formed by filling the opening with a conductive material. In some embodiments, a removing process may be performed on the rear surface of the substrate, and then, a process of forming the penetration electrode may be performed.

Next, the substrates may be bonded to each other in such a way that the rear surface of the second pixel substrate 200 faces the front surface of the first pixel substrate 100. At a bonding interface of the substates, the bonding pad 280 of the second pixel substrate 200 may be aligned and bonded to the bonding pad 180 of the first pixel substrate 100.

Referring to FIG. 19C, a rear portion of the first pixel substrate 100 may be partially removed, an insulating layer may be formed on a rear surface of the first pixel substrate 100, and an optical element may be formed thereon. In some embodiments, this process may be performed by the method described with reference to FIGS. 15C and 15D.

Referring to FIG. 19D, the passivation layer 376 may be formed on the rear surface of the logic/peripheral substrate 300, and an opening may be formed and may penetrate the logic/peripheral substrate 300 through the rear surface thereof. Next, the insulating layer 395 may be formed in the opening, and the penetration electrode 394 may be formed by filling the opening with a conductive material. In some embodiments, the penetration electrode 394 may be connected to the landing pad 347 of the logic/peripheral substrate 300.

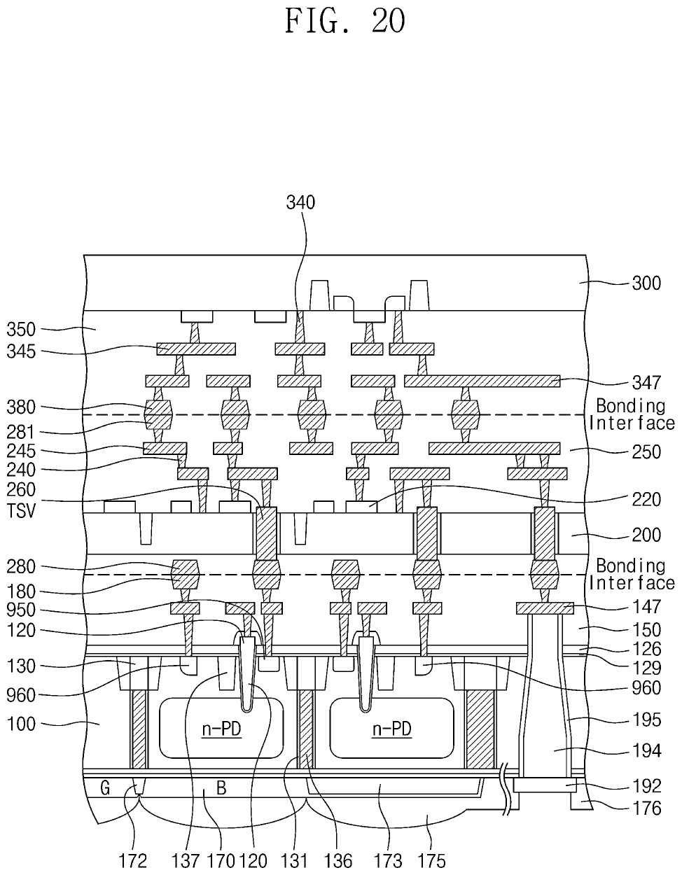

FIG. 20 is a sectional view of a CIS device, which may include a unit pixel circuit and a logic circuit and may be fabricated by a method according to some embodiments of the inventive concepts. Embodiments according to FIG. 20 may differ from the embodiments according to FIG. 19 in that a pad region is defined on the rear surface of the first pixel substrate 100 and the penetration electrode 194 may be formed by forming an opening in a back-side etching manner.

For example, embodiments may be related to, a dual vertical transfer gate, which includes a pair of poles, which may be extended to an n-type region of a photodiode, and includes a first insulating pattern, which may be formed on the substrate and between the poles, and is also related to a CIS device including the same. The CIS device may include a stack image sensing device, in which one or two pixel substrates and a logic/peripheral substrate are stacked. The stack image sensing device may be fabricated using a wafer bonding technology. In some embodiments, the CIS device may be fabricated by a method of stacking the second pixel substrate 200 on the pixel substrate 100 to face the front surface of the logic/peripheral substrate 300 and the front surface of the second pixel substrate 200 to each other.

Some embodiments of the inventive concepts may be realized using an integrated circuit technology of forming a semiconductor device on a substrate. Furthermore, the inventive concepts may be applicable to a substrate stacking technology, without a complicated process or an additional complicated process. As the performance and integration of the image sensing device increase, it is expected that the applicability and technical effects of the inventive concept may increase even more.

The inventive concepts may be related to an image sensing device, which includes a semiconductor device. However, some embodiments based on the inventive concepts may be applicable to not only electrical and electronic products but also medical, health, architectural, mechanical, and automotive electronic products in a directly applicable manner or in an integrated manner.

According to some embodiments of the inventive concepts, a gate, which may include a pair of poles, may be provided to transfer negative charges from a photodiode (PD), which may be formed deeply in a substrate, to a floating diffusion (FD) region, and it may be possible to prevent a negative charge backflow issue, which may occur in this structure (e.g., by a strong electric field produced by the paired poles and a connecting portion). A transistor according to some embodiments and a device therewith may exhibit relatively good negative charge mobility and relatively high optical conversion efficiency.

As an image sensing device becomes more integrated, the unit pixel circuit may become smaller, the photodiode PD may become deeper, the gate poles may become thinner, and the distance between the poles may become narrower. According to some embodiments of the inventive concepts, it may be possible to prevent the backflow issue, which may be caused by the device scaling down or an increase of electric field. In addition, it may be possible to prevent the electric field from increasing in a region not only between the poles of the gate but also outside the poles. This means that the effect of the inventive concept may be more effective for a small sized device and a scaled-down fabrication process.

Furthermore, the paired poles of the gate may be connected to each other without an additional interconnection line. Thus, it may be possible to simplify an interconnection structure and prevent a misalignment issue, which may occur when a contact is formed to connect the interconnection line to the gate poles. That is, it may be possible to increase a margin in designing and fabricating the image sensing device.

The pixel size is being decreased to increase the integration density and performance of the image sensing device. To realize a reduced pixel size, a high performance, and an effective disposition, a stack image sensing device may be fabricated using a substrate stacking technology. According to some embodiments of the inventive concepts, a pixel substrate fabrication process may be performed to separately form a pixel circuit on two pixel substrates, and then, the pixel substrates may be bonded to each other. Accordingly, the image sensing device may be fabricated using a substrate stacking technology, without a complex or numerous additional processes. The inventive concept may be integrated relatively easily with an advanced process, which may be used to increase the performance and integration density of the image sensing device. Therefore, it is expected that the inventive concept will be used more widely as the image sensing device becomes more miniaturized.

According to some embodiments of the inventive concepts, a first insulating pattern may be formed between a substrate surface and the paired poles to weaken an electric field between the paired poles. Accordingly, it may be possible to prevent a potential hump of hindering transfer of negative charges from a region between the paired poles to the FD region and a backflow issue, in which the negative charge flows in a reverse direction from the FD region to the region between the poles.

While some examples of embodiments of the inventive concepts have been particularly shown and described, it will be understood by one of ordinary skill in the art that variations in form and detail may be made therein without departing from the scope of the attached claims.

1. A transistor, comprising:
a gate;
an n-type source region below the gate;
an n-type drain region in a substrate adjacent to the gate;
a gate insulating layer between the gate and the substrate; and
a first insulating pattern between the gate insulating layer and the substrate,
wherein the gate comprises:
a pair of poles that extend to the source region; and
a connecting portion that connects the paired poles, and
wherein the first insulating pattern is between the poles.

2. The transistor of claim 1, wherein a thickness of the first insulating pattern is in a range from 5 nm to 50 nm.

3. The transistor of claim 1, wherein the first insulating pattern comprises SixNy, where x and y are real numbers greater than 0.

4. The transistor of claim 1, wherein a width of the pole is in a range from 50 nm to 200 nm, when measured at a surface level of the substrate.

5. The transistor of claim 1, wherein a depth of the pole is in a range from 200 nm to 500 nm, when measured from a surface of the substrate.

6. The transistor of claim 5, wherein an aspect ratio of the pole is in a range from 1 to 10.

7. The transistor of claim 4, wherein a distance between the poles is in a range from 10 nm to 80 nm, when measured at a surface level of the substrate.

8. The transistor of claim 1, wherein the first insulating pattern is a single or composite layer, which is formed of at least one of SiON, SiONC, SiO₂, or SiOC.

9. The transistor of claim 3, wherein the first insulating pattern comprises a void.

10. The transistor of claim 3, further comprising an etch stop layer, which is placed on the substrate adjacent to the gate and coplanar with the first insulating pattern.

11.-24. (canceled)

25. An image sensing device, comprising:
a first substrate including a photodiode region, a transfer transistor, and a floating diffusion region, the transfer transistor comprising a gate including a pair of poles, which are extended to an n-type region of the photodiode, and a connecting portion, which connect the poles of the pair of poles to each other, and a first insulating pattern between the poles of the pair of poles;
a second substrate including a source follower transistor; and
a third substrate including a logic circuit,
wherein the floating diffusion region of the first substrate is electrically connected to a gate of the source follower transistor of the second substrate.

26. The image sensing device of claim 25, wherein the floating diffusion region of the first substrate is connected to the gate of the source follower transistor of the second substrate in a Cu—Cu bonding manner.

27. The image sensing device of claim 26, wherein a front surface of the third substrate is connected to a rear surface of the second substrate.

28. The image sensing device of claim 26, further comprising:
a via that penetrates a rear surface of the third substrate; and
an I/O pad connected to the via.

29. The image sensing device of claim 25, wherein the floating diffusion region of the first substrate is connected to the gate of the source follower transistor of the second substrate through a via, which penetrates the second substrate.

30. The image sensing device of claim 29, wherein a front surface of the third substrate is connected to a front surface of the second substrate.

31. The image sensing device of claim 29, further comprising:
a via that penetrates a rear surface of the third substrate; and
an I/O pad connected to the via.

32. The image sensing device of claim 30, wherein the second substrate and the third substrate are connected to each other in a Cu—Cu bonding manner.

33. The image sensing device of claim 29, wherein the first substrate comprises metal lines provided in a double layered structure.

34. The image sensing device of claim 26, further comprising a dummy bonding pad that connects the first substrate to the second substrate.
